(19) United States
(12) Patent Application Publication
(10) Pub. No.: US 2025/0212503 A1
(43) Pub. Date: Jun. 26, 2025

(54) INTEGRATED CIRCUIT DEVICE

(71) Applicant: Samsung Electronics Co., Ltd., Suwon-si (KR)

(72) Inventors: Byungho MOON, Suwon-si (KR); Donghoon HWANG, Suwon-si (KR); Hyojin KIM, Suwon-si (KR); Kyoungmi PARK, Suwon-si (KR); Namhyun LEE, Suwon-si (KR)

(73) Assignee: Samsung Electronics Co., Ltd., Suwon-si (KR)

(21) Appl. No.: 18/825,193

(22) Filed: Sep. 5, 2024

(30) Foreign Application Priority Data
Dec. 20, 2023 (KR) 10-2023-0187517

(51) Int. Cl. H01L 27/088; H01L 21/8234; H01L 29/06; H01L 29/08; H01L 29/423; H01L 29/66; H01L 29/775; H01L 29/786

(52) U.S. Cl. CPC H10D 84/83; H10D 30/014; H10D 30/43; H10D 30/6735; H10D 30/6757; H10D 62/121; H10D 62/151; H10D 84/0135; H10D 84/0144; H10D 84/0149; H10D 84/038

(57) ABSTRACT

An integrated circuit device may include semiconductor regions; an insulating wall extending in a first lateral direction and passing in a vertical direction between a pair of semiconductor regions adjacent to each other in a second lateral direction among the semiconductor regions, a pair of nanosheet stacks overlapping the pair of semiconductor regions in the vertical direction and facing frontside surfaces of the pair of semiconductor regions, a pair of source/drain regions, and a backside contact. Each nanosheet stack may include a nanosheet having one end contacting a sidewall of the insulating wall in the second lateral direction. A contact end portion of the backside contact may be connected to one of the pair of source/drain regions. A contact sidewall of the backside contact may contact the insulating wall. The second lateral direction may be perpendicular to the first lateral direction.

### CROSS-REFERENCE TO RELATED APPLICATION

This application is based on and claims priority under 35 U.S.C. § 119 to Korean Patent Application No. 10-2023-0187517, filed on Dec. 20, 2023 in the Korean Intellectual Property Office, the disclosure of which is incorporated by reference herein in its entirety.

### BACKGROUND

Inventive concepts relate to an integrated circuit (IC) device, and more particularly, to an IC device including a backside contact structure.

The downscaling of IC devices has rapidly progressed due to the development of electronics technology. Because highly downscaled IC devices may require not only a high operating speed but also high operating accuracy, it may be necessary to provide wiring structures including conductive lines having a stable and optimized arrangement structure within a relatively small area and an insulation structure configured to limit and/or prevent undesired short-circuits between a plurality of conductive regions.

### SUMMARY

Inventive concepts provide an integrated circuit (IC) device, which includes a plurality of wiring structures arranged in a reduced area with the downscaling trend, and has a structure capable of improving electrical properties and reliability of the plurality of wiring structure.

According to an embodiment of inventive concepts, an IC device may include a plurality of semiconductor regions, an insulating wall, a pair of nanosheet stacks, a pair of source/drain regions, and a backside contact. Each of the plurality of semiconductor regions may have a front surface and a backside surface that face opposite directions. The insulating wall may extend in a first lateral direction. The insulating wall may pass in a vertical direction between a pair of semiconductor regions that are adjacent to each other in a second lateral direction, from among the plurality of semiconductor regions. The second lateral direction may be perpendicular to the first lateral direction. The pair of nanosheet stacks may overlap the pair of semiconductor regions in the vertical direction and may face frontside surfaces of the pair of semiconductor regions. Each nanosheet stack, among the pair of nanosheet stacks, may include a nanosheet having one end contacting a sidewall of the insulating wall. Each source/drain region, among the pair of source/drain regions, may include a portion in contact with the nanosheet of a corresponding one of the pair of nanosheet stacks. The backside contact may have a contact end portion and a contact sidewall. The contact end portion may be connected to a corresponding source/drain region among the pair of source/drain regions. The contact sidewall may contact a sidewall of the insulating wall. The backside contact may extend in the vertical direction from the contact end portion toward the backside surface of each of the pair of semiconductor regions.

According to an embodiment of inventive concepts, an IC device may include a plurality of semiconductor regions spaced apart from each other in a first lateral direction and a second lateral direction that are perpendicular to each other, each of the plurality of semiconductor regions having a frontside surface and a backside surface that face opposite directions; a plurality of nanosheet stacks facing the plurality of semiconductor regions in a vertical direction, each of the plurality of nanosheet stacks including a nanosheet; a plurality of source/drain regions, each of the plurality of source/drain regions being between a pair of nanosheet stacks that are adjacent to each other in the first lateral direction from among the plurality of nanosheet stacks, and each of the plurality of source/drain regions contacting the nanosheet in an adjacent nanosheet stack adjacent among the plurality of nanosheet stacks; an insulating wall, the insulating wall passing in the vertical direction between a pair of semiconductor regions that are adjacent to each other in the second lateral direction among the plurality of semiconductor regions, the insulating wall passing between a pair of nanosheet stacks that are adjacent to each other in the second lateral direction among the plurality of nanosheet stacks, and the insulating wall passing between a pair of source/drain regions that are adjacent to each other in the second lateral direction from among the plurality of source/drain regions; and a pair of backside contacts. Each backside contact in the pair of backside contacts may include a contact end portion connected to a corresponding one of the pair of source/drain regions and a contact sidewall contacting the insulating wall. Each backside contact in the pair of backside contacts may extend from the contact end portion toward the backside surface of each of the pair of semiconductor regions in the vertical direction.

According to an embodiment of inventive concepts, an IC device may include a plurality of semiconductor regions spaced apart from each other in a first lateral direction and a second lateral direction that are perpendicular to each other, each of the plurality of semiconductor regions having a frontside surface and a backside surface that face opposite directions; a plurality of nanosheet stacks facing the plurality of semiconductor regions in a vertical direction, each of the plurality of nanosheet stacks including a nanosheet; a plurality of source/drain regions, each of the plurality of source/drain regions being between a pair of nanosheet stacks that are adjacent to each other in the first lateral direction among the plurality of nanosheet stacks, and each of the plurality of source/drain regions contacting the nanosheet in an adjacent nanosheet stack among the plurality of nanosheet stacks; an insulating wall, the insulating wall passing in the vertical direction between a pair of semiconductor regions that are adjacent to each other in the second lateral direction among the plurality of semiconductor regions, the insulating wall passing between a pair of nanosheet stacks that are adjacent to each other in the second lateral direction among the plurality of nanosheet stacks, and the insulating wall passing between a pair of source/drain regions that are adjacent to each other in the second lateral direction among the plurality of source/drain regions; and a plurality of backside contact structures contacting the insulating wall, the plurality of backside contact structures being arranged in a line in the first lateral direction. Each of the plurality of backside contact structures may include a backside contact having a contact end portion connected to a corresponding one of the plurality of source/drain regions and a contact sidewall contacting the insulating wall. The backside contact may extend from the contact end portion toward the backside surface in the vertical direction. A width of the backside contact in the second lateral direction may gradually increase as the backside contact becomes closer toward the backside surface. A width of the insulating wall in the second lateral direction may gradually decrease as the insulating wall becomes closer toward the backside surface. In each of the plurality of backside contact structures, the contact sidewall of the backside contact may extend in a straight line in the first lateral direction.

### BRIEF DESCRIPTION OF THE DRAWINGS

Embodiments will be more clearly understood from the following detailed description taken in conjunction with the accompanying drawings in which:

FIG. 1 is a plan layout diagram of an integrated circuit (IC) device according to embodiments;

FIG. 2A is a cross-sectional view taken along line X1-X1′ of FIG. 1;

FIG. 2B is a cross-sectional view taken along line Y1-Y1′ of FIG. 1;

FIG. 2C is a cross-sectional view taken along line Y2-Y2′ of FIG. 1;

FIG. 3 is an enlarged cross-sectional view of a region corresponding to portion “EX1” of FIG. 2B;

FIG. 4 is a plan view of some components of the IC device shown in FIG. 1;

FIG. 5 is a plan view of an IC device according to embodiments;

FIGS. 6A and 6B are cross-sectional views of an IC device according to embodiments;

FIG. 6C is a plan view of some components of the IC device shown in FIGS. 6A and 6B;

FIG. 7 is a cross-sectional view of an IC device according to embodiments;

FIGS. 8A to 20B are diagrams of a process sequence of a method of manufacturing an IC device, according to embodiments, wherein FIGS. 8A, 9A, 10A, 11A, 12A, 13A, 14A, 15A, 16A, 17A, 18A, 19A, and 20A are cross-sectional views of an example sectional structure of a portion corresponding to the cross-section taken along line X1-X1′ of FIG. 1, according to a process sequence, FIGS. 8B, 9B, 10B, 11B, 12B, 13B, 16B, 17B, 18B, 19B, and 20B are cross-sectional views of an example sectional structure of a portion corresponding to the cross-section taken along line Y1-Y1′ of FIG. 1, according to a process sequence, FIGS. 12C, 14B, 15B, 16C, 17C, and 18C are cross-sectional views of an example sectional structure of a portion corresponding to the cross-section taken along line Y2-Y2′ of FIG. 1, according to a process sequence, and FIGS. 8C and 9C are plan views of some components according to a process sequence;

FIGS. 21A to 21C are plan views of a process sequence of a method of manufacturing an IC device, according to embodiments;

FIGS. 22A to 24C are diagrams of a process sequence of a method of manufacturing an IC device, according to embodiments, wherein FIGS. 22A, 23A, and 24A are cross-sectional views of an example sectional structure of a portion corresponding to the cross-section taken along line X1-X1′ of FIG. 1, according to a process sequence, FIGS. 22B, 23B, and 24B are cross-sectional views of an example sectional structure of a portion corresponding to the cross-section taken along line Y1-Y1′ of FIG. 1, according to a process sequence, and FIGS. 22C, 23C, and 24C are plan views of some components according to a process sequence; and

FIGS. 25A to 26C are diagrams of a process sequence of a method of manufacturing an IC device, according to embodiments, wherein FIGS. 25A and 26A are cross-sectional views of an example sectional structure of a portion corresponding to the cross-section taken along line X1-X1′ of FIG. 1, according to a process sequence, FIGS. 25B and 26B are cross-sectional views of an example sectional structure of a portion corresponding to the cross-section taken along line Y1-Y1′ of FIG. 1, according to a process sequence, and FIGS. 25C and 26C are plan views of some components according to a process sequence.

### DETAILED DESCRIPTION

As used herein, the singular forms “a,” “an” and “the” are intended to include the plural forms as well, unless the context clearly indicates otherwise.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The notion that elements are “substantially the same” may indicate that the element may be completely the same and may also indicate that the elements may be determined to be the same in consideration of errors or deviations occurring during a process.

Hereinafter, embodiments will be described in detail with reference to the accompanying drawings. The same reference numerals are used to denote the same elements in the drawings, and repeated descriptions thereof are omitted.

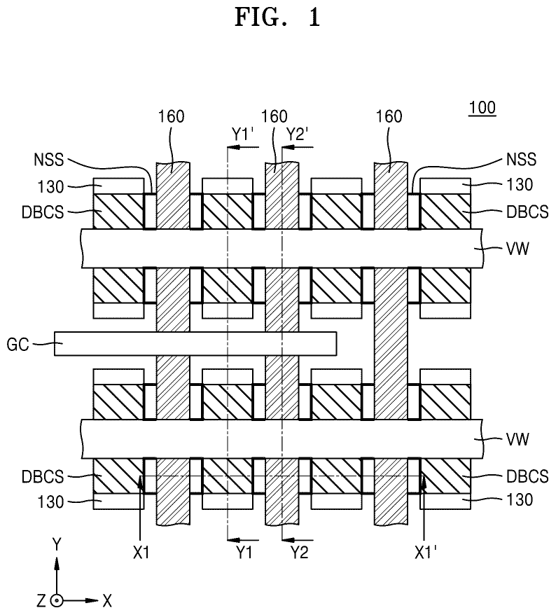

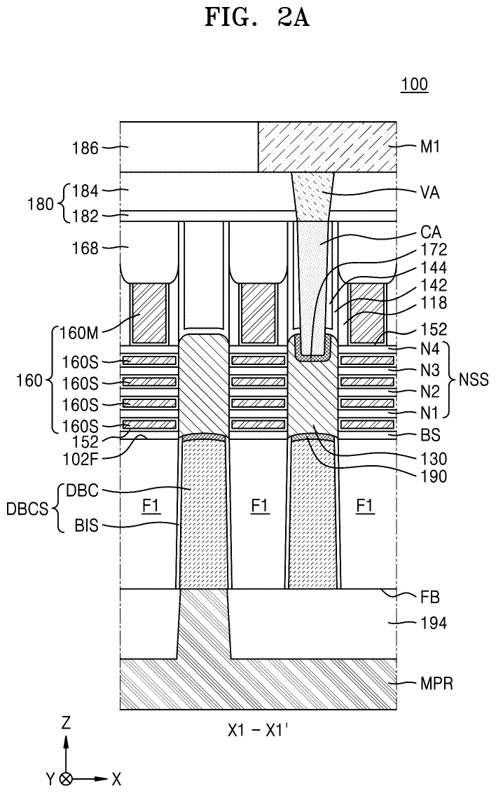

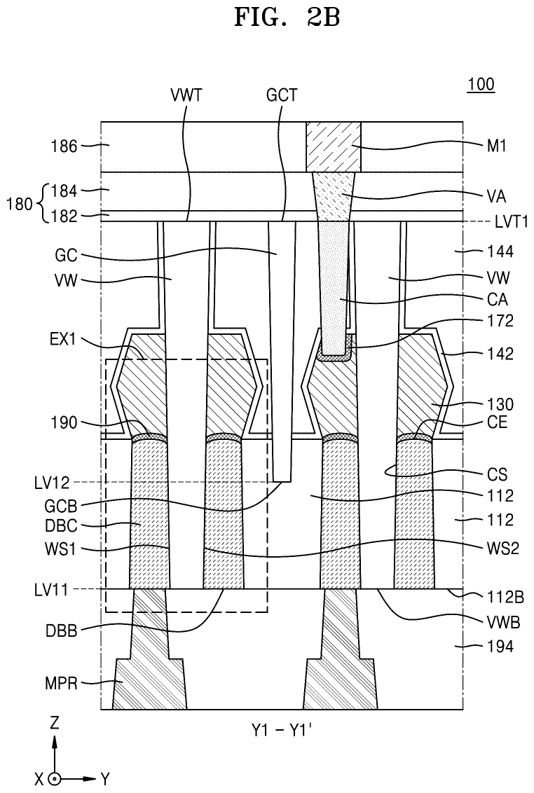

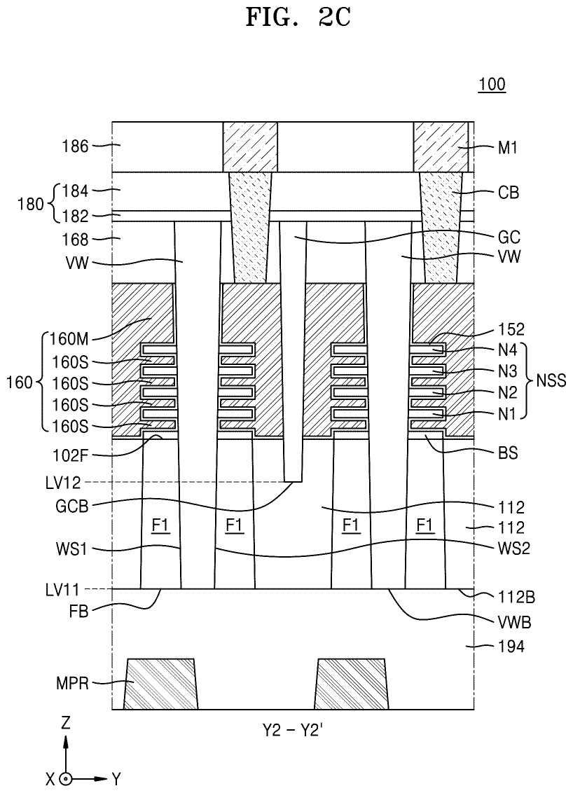

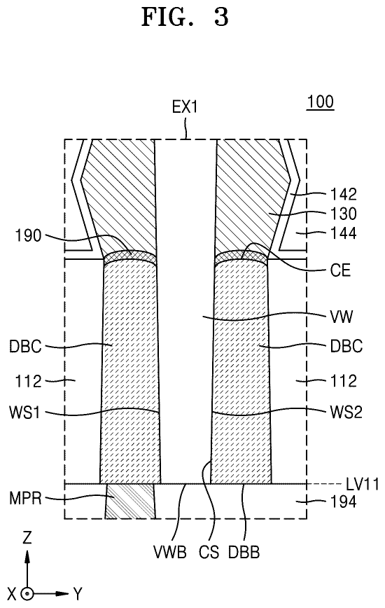

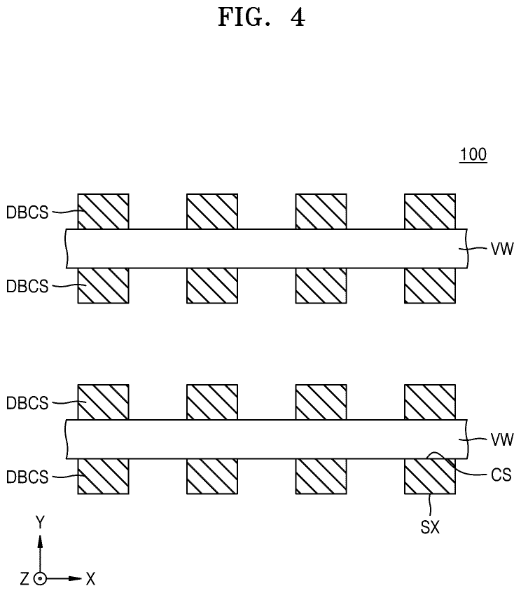

FIG. 1 is a plan layout diagram of an integrated circuit (IC) device 100 according to embodiments. FIG. 2A is a cross-sectional view taken along line X1-X1′ of FIG. 1. FIG. 2B is a cross-sectional view taken along line Y1-Y1′ of FIG. 1. FIG. 2C is a cross-sectional view taken along line Y2-Y2′ of FIG. 1. FIG. 3 is an enlarged cross-sectional view of portion “EX1” of FIG. 2B. FIG. 4 is a plan view of some components of the IC device 100 shown in FIG. 1. The IC device 100 including a field-effect transistor (FET) having a gate-all-around structure including an active region of a nanowire or nanosheet type and a gate surrounding the active region is described with reference to FIGS. 1 to 4.

Referring to FIGS. 1 to 3, the IC device 100 may include a plurality of semiconductor regions F1, which are apart from each other and arranged in a line in each of a first lateral direction (X direction) and a second lateral direction (Y direction) that are perpendicular to each other. In a view from a plane (X-Y plane), the plurality of semiconductor regions F1 may be arranged in a matrix form. Each of the plurality of semiconductor regions F1 may have a frontside surface 102F and a backside surface FB, which face opposite directions. In FIGS. 2A and 2C, the frontside surface 102F of each of the plurality of semiconductor regions F1 may be a surface facing a positive direction of a vertical direction Z direction), and the backside surface FB of each of the plurality of semiconductor regions F1 may be a surface facing an opposite direction of the vertical direction Z direction). Each of the plurality of semiconductor regions F1 may include silicon (Si). The semiconductor regions F1 also may be referred to as semiconductor structures.

A plurality of nanosheet stacks NSS may be on the plurality of semiconductor regions F1. Each of the plurality of nanosheet stacks NSS may overlap and face the semiconductor region F1 in the vertical direction (Z direction) and include at least one nanosheet. As used herein, the term “nanosheet” refers to a conductive structure having a cross-section that is substantially perpendicular to a direction in which current flows. The nanosheet may be interpreted as including a nanowire.

Although each of the plurality of nanosheet stacks NSS is illustrated as including a first nanosheet N1, a second nanosheet N2, a third nanosheet N3, and a fourth nanosheet N4 in the present embodiment, the number of nanosheets included in each of the plurality of nanosheet stacks NSS may be variously changed. For example, each of the plurality of nanosheet stacks NSS may include at least one nanosheet or at least two nanosheets, and the number of nanosheets included in the nanosheet stack NSS is not specifically limited. Each of the first to fourth nanosheets N1, N2, N3, and N4 may have a channel region. In embodiments, each of the first to fourth nanosheets N1, N2, N3, and N4 included in the nanosheet stack NSS may include a silicon (Si) layer, a silicon germanium (SiGe) film, or a combination thereof.

In embodiments, each of the first to fourth nanosheets N1, N2, N3, and N4 may have a thickness selected in a range of about 4 nm to about 6 nm in a vertical direction. In embodiments, the first to fourth nanosheets N1, N2, N3, and N4 may substantially have thickness. The first to fourth nanosheets N1, N2, N3, and N4 may include the same material.

The IC device 100 may include a plurality of source/drain regions 130. The plurality of source/drain regions 130 may be respectively on both sides of the plurality of nanosheet stacks NSS in the first lateral direction (X direction) and be respectively adjacent to the plurality of nanosheet stacks NSS.

Each of the plurality of source/drain regions 130 may be between a pair of nanosheet stacks NSS, which are adjacent to each other in the first lateral direction (X direction), from among the plurality of nanosheet stacks NSS). Each of the plurality of source/drain regions 130 may be in contact with each of the first nanosheet N1, the second nanosheet N2, the third nanosheet N3, and the fourth nanosheet N4, which are included in the nanosheet stack NSS adjacent thereto.

The IC device 100 may include a plurality of insulating walls VW, which are adjacent to the plurality of semiconductor regions F1, the plurality of nanosheet stacks NSS, and the plurality of source/drain regions 130 and extend long in the first lateral direction (X direction). The plurality of insulating walls VW may be apart from each other in the second lateral direction (Y direction) and extend parallel to each other in the first lateral direction (X direction). In embodiments, each of the plurality of insulating walls VW may include a silicon nitride layer, a silicon carbonitride (SiCN) film, a silicon oxycarbonitride (SiOCN) film, a silicon oxide layer, or a combination thereof, without being limited thereto.

Each of the plurality of insulating walls VW may pass in the vertical direction (Z direction) between a pair of semiconductor regions F1, which are adjacent to each other in the second lateral direction (Y direction) from among the plurality of semiconductor regions F1, between a pair of nanosheet stacks NSS, which are adjacent to each other in the second lateral direction (Y direction) from among the plurality of nanosheet stacks NSS, and between a pair of source/drain regions 130 which are adjacent to each other in the second lateral direction (Y direction) from among the plurality of source/drain regions 130.

The pair of semiconductor regions F1, which are adjacent to each other with one insulating wall VW therebetween in the second lateral direction (Y direction), may each contact the one insulating wall VW. The first nanosheet N1, the second nanosheet N2, the third nanosheet N3, and the fourth nanosheet N4, which are included in each of the pair of nanosheet sacks NSS that are adjacent to each other with one insulating wall VW therebetween in the second lateral direction (Y direction), may be in contact with the one insulating wall VW. The first nanosheet N1, the second nanosheet N2, the third nanosheet N3, and the fourth nanosheet N4 may each be in contact with the one insulating wall VW at one end in the second lateral direction (Y direction). The pair of source/drain regions 130, which are adjacent to each other with one insulating wall VW therebetween in the second lateral direction (Y direction) may each contact the one insulating wall VW.

From both sidewalls of each of the plurality of semiconductor regions F1 in the second lateral direction (Y direction), a sidewall opposite to a sidewall facing the insulating wall VW may be covered by a device isolation film 112. Each of a plurality of device isolation films 112 may include a silicon oxide layer, without being limited thereto.

The frontside surface 102F of the semiconductor region F1 may be covered by a bottom semiconductor layer BS between the semiconductor region F1 and the nanosheet stack NSS. The bottom semiconductor layer BS may include silicon (Si). In embodiments, a thickness of the bottom semiconductor layer BS in the vertical direction Z direction) may be less than a thickness of each of the first nanosheet N1, the second nanosheet N2, the third nanosheet N3, and the fourth nanosheet N4 included in the nanosheet stack NSS.

On the semiconductor region F1, a plurality of gate lines 160 may be apart from each other in the first lateral direction (X direction) and extend long in the second lateral direction (Y direction). Each of the plurality of gate lines 160 may surround the first to fourth nanosheets N1, N2, N3, and N4 while covering the plurality of nanosheet stacks NSS on the bottom semiconductor layer BS.

Each of the plurality of source/drain regions 130 may be adjacent to at least one gate line 160 selected from the plurality of gate lines 160. The plurality of source/drain regions 130, which are arranged in a line in the first lateral direction (X direction), may be each between two adjacent ones of the plurality of gate lines 160. Each of the plurality of source/drain regions 130 may have surfaces in contact with the first to fourth nanosheets N1, N2, N3, and N4 included in the nanosheet stack NSS adjacent thereto.

The plurality of source/drain regions 130 may each include an epitaxially grown semiconductor layer. In embodiments, the plurality of source/drain regions 130 may include an epitaxially grown Si layer, an epitaxially grown SiC layer, or a plurality of epitaxially grown SiGe layers. When the source/drain region 130 is included in an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 is included in a PMOS transistor, the source/drain region 130 may include a SiGe layer doped with a p-type dopant. The p-type dopant may be selected from boron (B) and gallium (Ga).

As shown in FIGS. 2A and 2C, each of the plurality of gate lines 160 may include a main gate portion 160M and a plurality of sub-gate portions 160S. The main gate portion 160M may cover a top surface of the nanosheet stack NSS and extend in the second lateral direction (Y direction). The plurality of sub-gate portions 160S may be integrally connected to the main gate portion 160M and respectively be in spaces between the first to fourth nanosheets N1, N2, N3, and N4. In the vertical direction Z direction), a thickness of each of the plurality of sub-gate portions 160S may be less than a thickness of the main gate portion 160M.

The plurality of gate lines 160 may include a metal, a metal nitride, a metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum nitride (TaN). The metal carbide may include titanium aluminum carbide (TiAlC). However, a material included in the plurality of gate lines 160 is not limited to the examples described above.

A gate dielectric film 152 may be between the nanosheet stack NSS and the gate line 160. The gate dielectric film 152 may have a stack structure of an interface dielectric film and a high-k dielectric film. The interface dielectric film may include a low-k dielectric material film (e.g., a silicon oxide film, a silicon oxynitride film, or a combination thereof), which has a dielectric constant of about 9 or less. In embodiments, the interface dielectric film may be omitted. The high-k dielectric film may include a material having a higher dielectric constant than a silicon oxide film. For example, the high-k dielectric film may have a dielectric constant of about 10 to 25. The high-k dielectric film may include hafnium oxide, without being limited thereto.

As shown in FIG. 2A, both sidewalls of each of the plurality of sub-gate portions 160S included in the plurality of gate lines 160 may be apart from the source/drain region 130 with the gate dielectric film 152 therebetween. The gate dielectric film 152 may be between the sub-gate portion 160S included in the gate line 160 and each of the first to fourth nanosheets N1, N2, N3, and N4, between the sub-gate portion 160S included in the gate line 160 and the source/drain region 130, and a lowermost one of the sub-gate portions 160S and the bottom semiconductor layer BS. The gate dielectric film 152 may include portions in contact with the bottom semiconductor layer BS.

The plurality of gate lines 160, the plurality of nanosheet stacks NSS, and the plurality of source/drain regions 130 may constitute a plurality of nanosheet transistors. The plurality of nanosheet transistors may include an NMOS transistor, a PMOS transistor, or a combination thereof.

As shown in FIG. 2A, both sidewalls of the gate line 160 may be covered by a plurality of insulating spacers 118. Each of the plurality of insulating spacers 118 may cover a sidewall of the main gate portion 160M on a top surface of the nanosheet stack NSS. Each of the plurality of insulating spacers 118 may be apart from the gate line 160 with the gate dielectric film 152 therebetween. The plurality of insulating spacers 118 may each include silicon nitride, silicon oxide, silicon oxycarbide (SiOC), silicon oxycarbonitride (SiOCN), silicon carbonitride (SiCN), silicon boron nitride (SiBN), silicon oxynitride (SiON), silicon boron carbonitride (SiBCN), SiOF, SiOCH, or a combination thereof. Each of the plurality of insulating spacers 118 may include a single film including one material film selected from the materials described above or a multilayered film including a plurality of material films selected from the materials described above.

As shown in FIGS. 2A and 2C, a top surface of each of the gate line 160, the gate dielectric film 152, and the insulating spacer 118 may be covered by a capping insulating pattern 168. The capping insulating pattern 168 may include a silicon nitride layer.

The plurality of source/drain regions 130, the device isolation film 112, and the plurality of insulating spacers 118 may be covered by an insulating liner 142. An inter-gate dielectric film 144 may be on the insulating liner 142. The inter-gate dielectric film 144 may be between a pair of gate lines 160, which are adjacent to each other in the first lateral direction (X direction) and between a pair of source/drain regions 130, which are adjacent to each other. In embodiments, the insulating liner 142 may include silicon nitride, SiCN, SiBN, SION, SiOCN, SiBCN, or a combination thereof, without being limited thereto. The inter-gate dielectric film 144 may include a silicon oxide film, without being limited thereto.

As shown in FIGS. 2A and 2B, a plurality of frontside source/drain contacts CA may be on the plurality of source/drain regions 130 between a pair of adjacent ones of the plurality of gate lines 160. Each of the plurality of frontside source/drain contacts CA may be electrically connected to at least one source/drain region 130 selected from the plurality of source/drain regions 130. For example, one frontside source/drain contact CA may be connected to one source/drain region 130 or a plurality of source/drain regions 130 that are adjacent to each other.

A metal silicide film 172 may be between the source/drain region 130 and the frontside source/drain contact CA. The metal silicide film 172 may be in contact with the source/drain region 130. The frontside source/drain contact CA may pass through the inter-gate dielectric film 144 and the insulating liner 142 in the vertical direction Z direction) and contact the metal silicide film 172 and the frontside source/drain contact CA. The frontside source/drain contact CA may be connected to the source/drain region 120 through the metal silicide film 172. The frontside source/drain contact CA may pass through a portion of the source/drain region 130 in the vertical direction Z direction). The insulating liner 142 and the inter-gate dielectric film 144 may surround a sidewall of the frontside source/drain contact CA.

In embodiments, the metal silicide film 172 may include Ti, W, Ru, Nb, Mo, Hf, Ni, Co, Pt, Yb, Tb, Dy, Er, or Pd. For example, the metal silicide film 172 may include titanium silicide. In embodiments, the frontside source/drain contact CA may include only a metal plug including a single metal. In other embodiments, the frontside source/drain contact CA may include a metal plug and a conductive barrier film surrounding the metal plug. The metal plug may include a metal selected from molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include titanium (Ti), tantalum (Ta), tungsten (W), titanium nitride (TiN), tantalum (TaN), tungsten nitride (WN), tungsten carbon nitride (WCN), titanium silicon nitride (TiSiN), tantalum silicon nitride (TaSiN), tungsten silicon nitride (WSiN), or a combination thereof, without being limited thereto.

As shown in FIGS. 2A, 2B, and 3, the IC device 100 may include a plurality of backside contact structures DBCS. Each of the plurality of backside contact structures DBCS may include a backside contact DBC and a backside insulating spacer BIS. The backside insulating spacer BIS may be between the backside contact DBC and the semiconductor region F1 that is most adjacent to the backside contact DBC. The backside contact DBC may be apart from the semiconductor region F1 with the backside insulating spacer BIS therebetween in the first lateral direction (X direction).

As shown in FIG. 3, the backside contact DBC of each of the plurality of backside contact structures DBCS may have a contact end portion CE connected to a selected one of the plurality of source/drain regions 130 and a contact sidewall CS facing the insulating wall VW. Each of the plurality of backside contact structures DBCS may extend from the contact end portion CE toward the backside surface FB of the semiconductor region F1 in the vertical direction (Z direction).

As shown in FIG. 4, the plurality of backside contact structures DBCS may include a plurality of groups of backside contact structures DBCS, which are arranged in a line in the first lateral direction (X direction). In each of the plurality of backside contact structures DBCS, the contact sidewall CS of the backside contact DBC and a sidewall SX opposite to the contact sidewall CS may each extend in a straight line in the first lateral direction (X direction). As shown in FIG. 2B, of the backside contact DBC included in each of the plurality of backside contact structures DBCS, the contact sidewall CS facing the insulating wall VW adjacent to the backside contact DBC may be in contact with the insulating wall VW adjacent thereto.

As shown in FIG. 2B, the insulating wall VW may have a shape with a width in the second lateral direction (Y direction) gradually decreasing toward the backside surface FB of the semiconductor region F1. Both sidewalls WS1 and WS2 of the insulating wall VW in the second lateral direction (Y direction), which contact the backside contact DBC, may each include an inclined surface that is inclined with respect to the vertical direction Z direction). The backside contact DBC may have a shape with a width in the second lateral direction (Y direction) gradually increasing toward the backside surface FB of the semiconductor region F1. The contact sidewall CS of the backside contact DBC, which contacts the insulating wall VW, may include an inclined surface corresponding to an inclined shape of the sidewalls WS1 and WS2 of the insulating wall VW.

A metal silicide film 190 may be between the source/drain region 130 and the backside contact structure DBCS. The metal silicide film 190 may be in contact with the source/drain region 130 and the backside contact structure DBCS. As shown in FIG. 2A, the backside contact structure DBCS may contact the metal silicide film 190 by passing in the vertical direction Z direction) between a pair of semiconductor regions F1, which are adjacent to each other in the first lateral direction (X direction), from among the plurality of semiconductor regions F1.

The backside contact DBC may be connected to the source/drain region 130 through the metal silicide film 190. A constituent material of the metal silicide film 190 is the same as that of the metal silicide film 172, which is described above. In embodiments, the backside contact DBC may include only a metal plug including a single metal. In other embodiments, the backside contact DBC may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), or a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto.

Each of a plurality of backside contacts DBC may be connected to a surface opposite to a surface facing the inter-gate dielectric film 144, of a selected one of the plurality of source/drain regions 130.

As shown in FIG. 2B, the device isolation film 112 may cover the sidewall (refer to SX in FIG. 4) of the backside contact DBC, which is opposite to the contact sidewall CS contacting the insulating wall VW. The device isolation film 112 may be in contact with the sidewall SX opposite to the backside contact DBC. A device isolation lowermost surface 112B of the device isolation film 112, which is closest to the backside surface FB of the semiconductor region F1, and a wall lowermost surface VWB of the insulating wall VW, which is closest to the backside surface FB of the semiconductor region F1, may extend on the same plane.

As shown in FIGS. 1, 2B, and 2C, the IC device 100 may include a gate cut insulating pattern GC defining a length of the plurality of gate lines 160 in the second lateral direction (Y direction). The gate cut insulating pattern GC may face one end of a corresponding one of the plurality of gate lines 160 in the second lateral direction (Y direction) and extend long in the first lateral direction (X direction). The gate cut insulating pattern GC may pass through a portion of the device isolation film 112 in the vertical direction (Z direction). Of the gate cut insulating pattern GC, a lowermost surface GCB closest to the backside surface FB of the semiconductor region F1 may be in contact with the device isolation film 112. The gate cut insulating pattern GC may include a silicon nitride layer, a silicon carbonitride film (SiCN film), a silicon oxycarbonitride film (SiOCN film), a silicon oxide layer, or a combination thereof, without being limited thereto.

As shown in FIGS. 2B and 2C, a vertical level LV11 of the lowermost surface VWB of the insulating wall VW, which is closest to the backside surface FB of the semiconductor region F1, may be closer to the backside surface FB of the semiconductor region F1 than a vertical level LV12 of the lowermost surface GCB of the gate cut insulating pattern GC, which is closest to the backside surface FB of the semiconductor region F1. A vertical level LVT1 of an uppermost surface VWT of the insulating wall VW, which is farthest from the lowermost surface VWB, may substantially be the same as a vertical level of an uppermost surface GCT of the gate cut insulating pattern GC. As used herein, the term “vertical level” refers to a relative distance in the vertical direction Z direction). For example, the term “vertical level” used herein may refer to a distance from the backside surface FB of each of the plurality of semiconductor regions F1 in a vertical direction (Z direction or −Z direction). As shown in FIGS. 2B and 3, the lowermost surface VWB of the insulating wall VW, which is closest to the backside surface FB of the semiconductor region F1, and a lowermost surface DBB of the backside contact DBC, which is closest to the backside surface FB of the semiconductor region F1, may extend on the same plane (X-Y plane) that extends at the vertical level LV11). As used herein, the lowermost surface VWB of the insulating wall VW may be referred to as a wall lowermost surface, and the lowermost surface DBB of the backside contact DBC may be referred to as a contact lowermost surface.

As shown in FIGS. 2A to 2C, a top surface of each of the frontside source/drain contact CA, a plurality of capping insulating patterns 168, and the inter-gate dielectric film 144 may be covered by an upper insulating structure 180. The upper insulating structure 180 may include an etch stop film 182 and an upper insulating film 184, which are sequentially stacked on each of the plurality of frontside source/drain contacts CA, the plurality of capping insulating patterns 168, and the inter-gate dielectric film 144. The etch stop film 182 may include silicon carbide (SiC), silicon nitride (SiN), silicon carbonitride (SiCN), silicon oxycarbide (SiOC), aluminum nitride (AlN), aluminum oxynitride (AlON), aluminum oxide (AlO), aluminum oxycarbide (AlOC), or a combination thereof. The upper insulating film 184 may include an oxide film, a nitride film, an ultralow-k (ULK) film having an ultralow dielectric constant K of about 2.2 to about 2.4, or a combination thereof. For example, the upper insulating film 184 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

A source/drain via contact VA may be on the frontside source/drain contact CA. Each of a plurality of source/drain via contacts VA may pass through the upper insulating structure 180 and contact the frontside source/drain contact CA. From among the plurality of source/drain regions 130, the source/drain region 130 connected to the frontside source/drain contact CA may be electrically connected to the source/drain via contact VA through the metal silicide film 172 and the frontside source/drain contact CA. Each of the plurality of source/drain via contacts VA may include molybdenum (Mo) or tungsten (W), without being limited thereto.

As shown in FIG. 2C, a gate contact CB may be on the gate line 160. The gate contact CB may pass through the upper insulating structure 180 and the capping insulating pattern 168 in the vertical direction Z direction) and be connected to the gate line 160. A bottom surface of the gate contact CB may contact a top surface of the gate line 160. The gate contact CB may include a contact plug, which includes molybdenum (Mo), copper (Cu), tungsten (W), cobalt (Co), ruthenium (Ru), manganese (Mn), titanium (Ti), tantalum (Ta), aluminum (Al), or a combination thereof, or an alloy thereof, but a constituent material of the contact plug is not limited thereto. In embodiments, the gate contact CB may further include a conductive barrier pattern, which surrounds a portion of the contact plug. The conductive barrier pattern included in the gate contact CB may include a metal or a metal nitride. For example, the conductive barrier pattern may include Ti, Ta, W, TiN, TaN, WN, WCN, TiSiN, TaSiN, WSiN, or a combination thereof, without being limited thereto.

A top surface of the upper insulating structure 180 may be covered by a frontside interlayer insulating film 186. A constituent material of the frontside interlayer insulating film 186 is substantially the same as that of the upper insulating film 184, which has been described above. The plurality of upper wiring layers M1 may pass through the frontside interlayer insulating film 186. The plurality of upper wiring layers M1 may include an upper wiring layer M1 connected to the source/drain via contact VA and an upper wiring layer M1 connected to the gate contact CB. The plurality of upper wiring layers M1 may include molybdenum (Mo), copper (Cu), tungsten (W), cobalt (Co), ruthenium (Ru), manganese (Mn), titanium (Ti), tantalum (Ta), aluminum (Al), or a combination thereof, or an alloy thereof, without being limited thereto.

As shown in FIGS. 2A to 2C, the IC device 100 may include a backside insulating film 194 covering the backside surface FB of each of the plurality of semiconductor regions F1 and a plurality of backside wiring structures MPR passing through the backside insulating film 194 in a vertical direction. The plurality of backside wiring structures MPR may include a backside wiring structure MPR connected to the backside contact DBC. In embodiments, a constituent material of the backside insulating film 194 is substantially the same as that of the upper insulating film 184, which has been described above. A constituent material of each of the plurality of backside wiring structures MPR is substantially the same as that of each of the plurality of upper wiring layers M1, which has been described above.

The IC device 100 described with reference to FIGS. 1 to 4 may include a plurality of backside contact structures DBCS, each of which includes the backside contact DBC connected to the source/drain region 130 from a backside adjacent to the backside surface FB of each of the plurality of semiconductor regions F1. According to the IC device 100, a size deviation of the plurality of backside contact structures DBCS may be minimized, thereby reducing a deviation of electrical characteristics among the plurality of backside contact structures DBCS. In addition, because the backside contact DBC included in each of the plurality of backside contact structures DBCS ensures a sufficient width in a lateral direction (X direction and/or Y direction), a contact resistance of each of the plurality of backside contacts DBC included in the plurality of backside contact structures DBCS may be reduced. Furthermore, a sufficient insulation distance may be ensured between two adjacent ones of the plurality of backside contacts DBC, and thus, undesired short circuits between the plurality of backside contacts DBC may be limited and/or prevented. Accordingly, the IC device 100 may provide a wiring structure having a stable and optimized structure even when the IC device 100 has a reduced area with a downscaling trend, and thus, the integration density and reliability of the IC device 100 may improve.

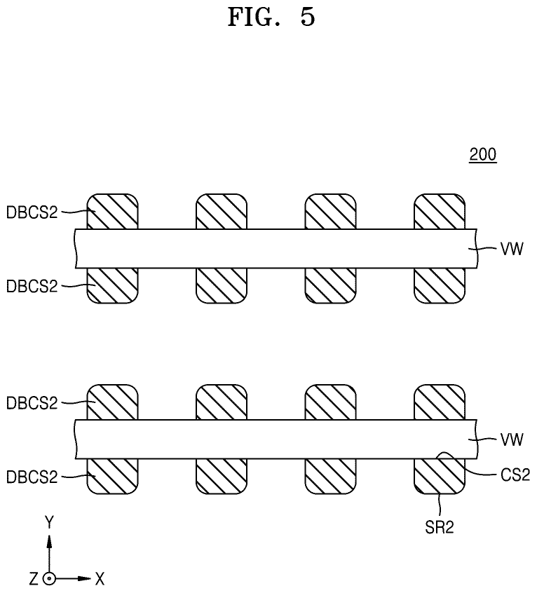

FIG. 5 is a plan view of an IC device 200 according to embodiments. A planar configuration of some components of the IC device 200 is illustrated in FIG. 5. In FIG. 5, the same reference numerals are used to denote the same elements as in FIGS. 1 to 4, and detailed descriptions thereof are omitted.

Referring to FIG. 5, the IC device 200 may substantially have the same configuration as the IC device 100 described with reference to FIGS. 1 to 4. However, the IC device 200 may include a plurality of backside contact structures DBCS2. The plurality of backside contact structures DBCS2 may respectively and substantially have the same configurations as the plurality of backside contact structures DBCS described with reference to FIGS. 1 to 4. Like the backside contact structure DBCS described with reference to FIGS. 1 to 4, each of the plurality of backside contact structures DBCS2 may include a backside contact and a backside insulating spacer between the backside contact and a semiconductor region F1 that is most adjacent to the backside contact. In the backside contact structure DBCS2, the backside contact and the backside insulating spacer may respectively and substantially have the same configurations as the backside contact DBC and the backside insulating spacer BIS described with reference to FIGS. 2A to 2C. In each of the plurality of backside contact structures DBCS2, the backside contact may have a contact sidewall CS2 facing the insulating wall VW.

The plurality of backside contact structures DBCS2 may include a plurality of groups of backside contact structures DBCS2, which are arranged in a line in a first lateral direction (X direction). In each of the plurality of backside contact structures DBCS2, the contact sidewall CS2 of the backside contact in contact with the insulating wall VW may extend in a straight line in the first lateral direction (X direction). In each of the plurality of backside contact structures DBCS2, at least a portion of a sidewall SR2 opposite to the contact sidewall CS2 may extend in a curved shape in the first lateral direction (X direction).

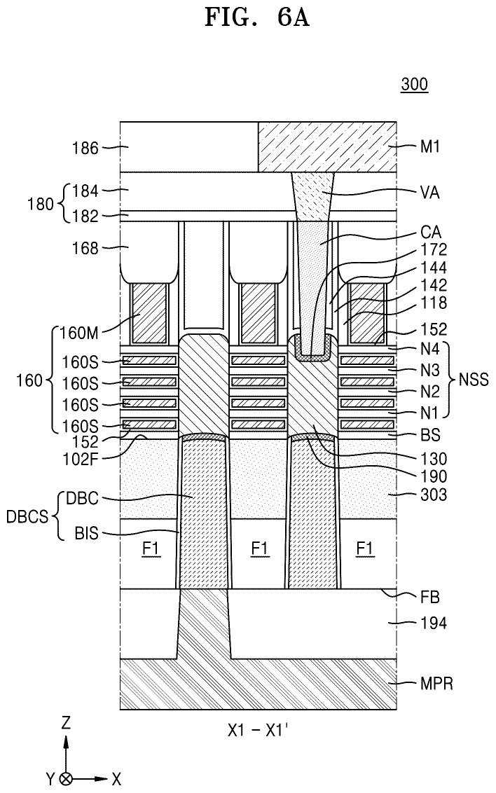

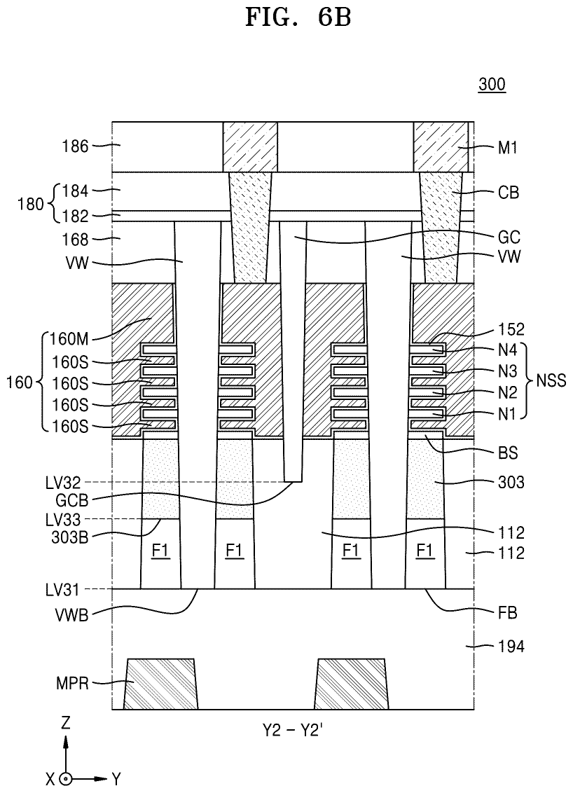

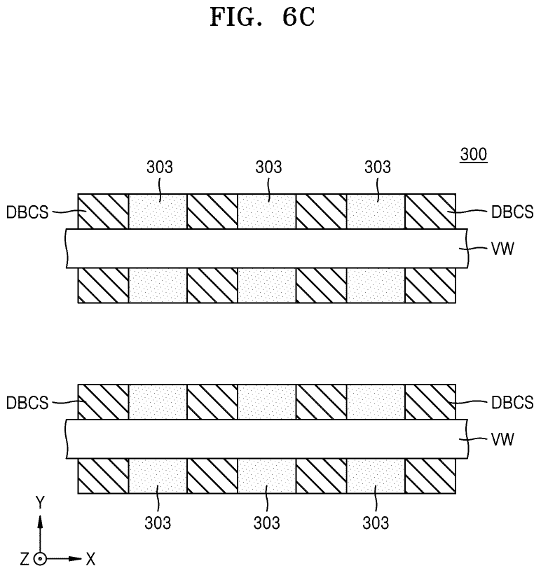

FIGS. 6A, 6B, and 6C are diagrams of an IC device 300 according to embodiments. FIG. 6A is a cross-sectional view of a portion corresponding to a cross-section taken along line X1-X1′ of FIG. 1 in the IC device 300. FIG. 6B is a cross-sectional view of a portion corresponding to a cross-section taken along line Y2-Y2′ of FIG. 1 in the IC device 300. FIG. 6C is a plan view of some components of the IC device 300. In FIGS. 6A, 6B, and 6C, the same reference numerals are used to denote the same elements as in FIGS. 1 to 4, and detailed descriptions thereof are omitted.

Referring to FIGS. 6A, 6B, and 6C, the IC device 300 may substantially have the same configuration as the IC device 100 described with reference to FIGS. 1 to 4. However, the IC device 300 may further include a plurality of substituted semiconductor regions 303 between a plurality of semiconductor regions F1 and the plurality of nanosheet stacks NSS. Each of the plurality of substituted semiconductor regions 303 may be in contact with a corresponding one of the plurality of semiconductor regions F1. Each of the plurality of substituted semiconductor regions 303 may include silicon (Si).

Each of a plurality of backside contact structures DBCS may be between a pair of semiconductor regions F1, which are adjacent to each other in a first lateral direction (X direction), and a pair of substituted semiconductor regions 303, which are adjacent to each other in the first lateral direction (X direction). Each of the plurality of backside contact structures DBCS may face the pair of substituted semiconductor regions 303, which are adjacent to each other in the first lateral direction (X direction). Each of the plurality of backside contact structures DBCS may be in contact with the pair of substituted semiconductor regions 303, which are adjacent to each other in the first lateral direction (X direction).

As shown in FIG. 6A, a backside contact DBC included in each of the plurality of backside contact structures DBCS may be apart from each of the semiconductor region F1 and the substituted semiconductor region 303, which are adjacent to each other in the first lateral direction (X direction) in a backside insulating spacer BIS therebetween.

As shown in FIG. 6B, a vertical level LV31 of a lowermost surface VWB of an insulating wall VW, which is closest to the backside surface FB of the semiconductor region F1, may be closer to the backside surface FB of the semiconductor region F1 than a vertical level LV32 of a lowermost surface GCB of the gate cut insulating pattern GC, which is closest to the backside surface FB of the semiconductor region F1. A vertical level LV33 of a lowermost surface 303B of each of the plurality of substituted semiconductor regions 303 may be closer to the backside surface FB of the semiconductor region F1 than the vertical level LV32 of the lowermost surface GCB of the gate cut insulating pattern GC, and be farther from the backside surface FB of the semiconductor region F1 than the vertical level LV31 of the lowermost surface VWB of the insulating wall VW.

As shown in FIG. 6C, the plurality of backside contact structures DBCS may include a plurality of groups of backside contact structures DBCS are arranged in a line in the first lateral direction (X direction), and one substituted semiconductor region 303 may be between a pair of adjacent ones of the plurality of groups of backside contact structures DBCS. From among the plurality of backside contact structures DBCS and the plurality of substituted semiconductor regions 303, the plurality of backside contact structures DBCS and the plurality of substituted semiconductor regions 303, which are arranged in a straight line in the first lateral direction (X direction), may be in contact with one insulating wall VW adjacent thereto.

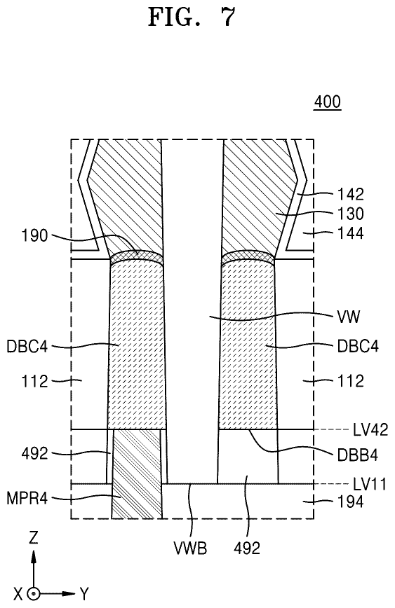

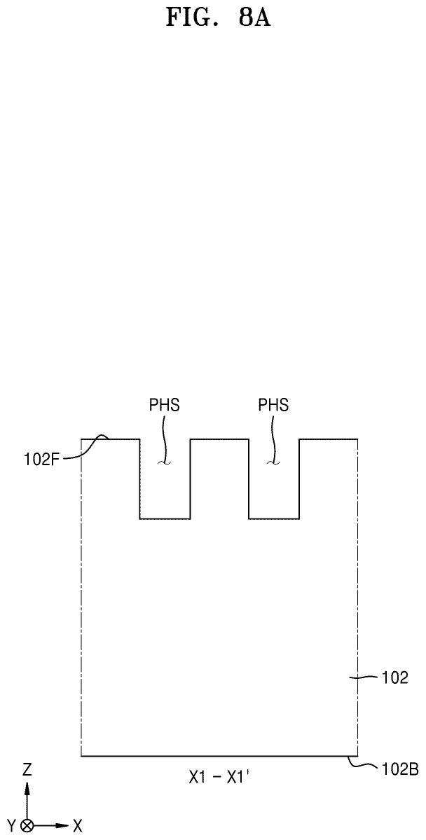

FIG. 7 is a cross-sectional view of an IC device 400 according to embodiments. FIG. 7 is an enlarged cross-sectional view of a region corresponding to portion “EX1” of FIG. 2B in the IC device 400. In FIG. 7, the same reference numerals are used to denote the same elements as in FIGS. 1 to 4, and detailed descriptions thereof are omitted.

Referring to FIG. 7, the IC device 400 may substantially have the same configuration as the IC device 100 described with reference to FIGS. 1 to 4. However, the IC device 400 may include a plurality of backside contacts DBC4. A vertical level LV42 of a lowermost surface DBB4 that is closest to a backside surface (refer to FB in FIG. 2C) of a semiconductor region F1, from among the plurality of backside contacts DBC4, may be farther from the backside surface FB of the semiconductor region F1 than a vertical level LV11 of a lowermost surface VWB that is closest to the backside surface FB of the semiconductor region F1, of an insulating wall VW. As used herein, the lowermost surface DBB4 of each of the plurality of backside contacts DBC4 may be referred to as a contact lowermost surface, and the lowermost surface VWB of the insulating wall VW may be referred to as a wall lowermost surface. The lowermost surface DBB4 of each of the plurality of backside contacts DBC4 may be covered by a gap-fill insulating film 492. The gap-fill insulating film 492 may be between the backside contact DBC4 and the backside insulating film 194 in a vertical direction (Z direction). A constituent material of the gap-fill insulating film 492 is substantially the same as that of the backside insulating film 194, which has been described with reference to FIGS. 2A to 2C.

A backside wiring structure MPR4 may pass through the gap-fill insulating film 492 in the vertical direction Z direction) and contact the backside contact DBC4. Details of the backside contact DBC4 and the backside wiring structure MPR4 are substantially the same as those of the backside contact DBC and the backside wiring structure MPR described above with reference to FIGS. 1 to 4.

Like the IC device 100 described with reference to FIGS. 1 to 4, the IC devices 200, 300, and 400 described with reference to FIGS. 5 to 7 may include a plurality of backside contact structures DBCS or DBCS2, each of which includes the backside contact DBC or DBC4 connected to a source/drain region 130 from a backside adjacent to the backside surface FB of each of a plurality of semiconductor regions F1. According to the IC devices 200, 300, and 400, a size deviation of the plurality of backside contact structures DBCS or DBCS2 may be minimized, thereby reducing a deviation of electrical characteristics among the plurality of backside contact structures DBCS or DBCS2. In addition, because the backside contact DBC or DBC4 included in each of the plurality of backside contact structures DBCS or DBCS2 ensures a sufficient width in a lateral direction (X direction and/or Y direction), a contact resistance of each of the plurality of backside contacts DBC or DBC4 included in the plurality of backside contact structures DBCS or DBCS2 may be reduced. Furthermore, a sufficient insulation distance may be ensured between two adjacent ones of the plurality of backside contacts DBC and DBC4, and thus, undesired short circuits between the plurality of backside contacts DBC and DBC4 may be limited and/or prevented. Accordingly, each of the IC devices 200, 300, and 400 may provide a wiring structure having a stable and optimized structure even when each of the IC devices 200, 300, and 400 has a reduced area with a downscaling trend, and thus, the integration density and reliability of each of the IC devices 200, 300, and 400 may improve.

Examples of a method of manufacturing an IC device, according to embodiments, are now described in detail.

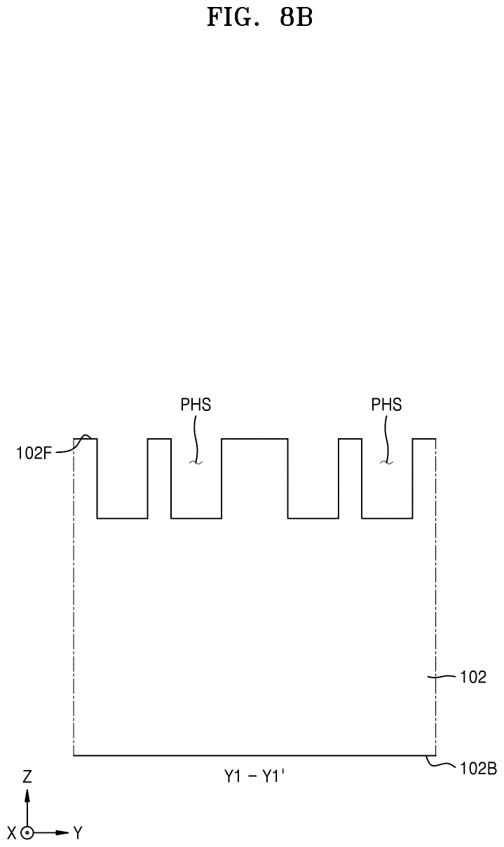

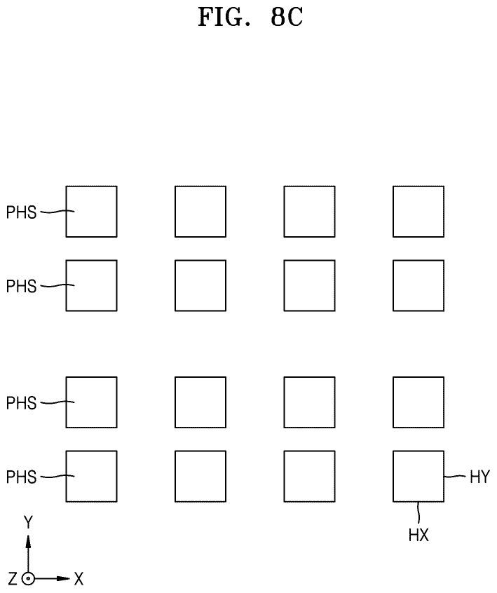

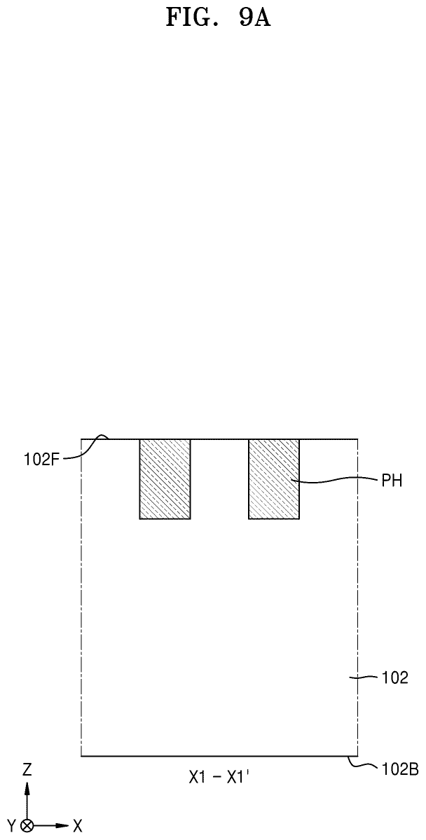

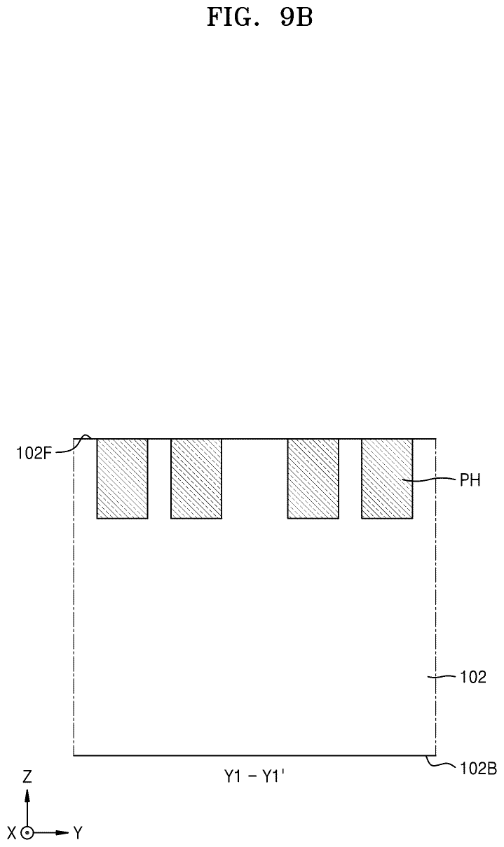

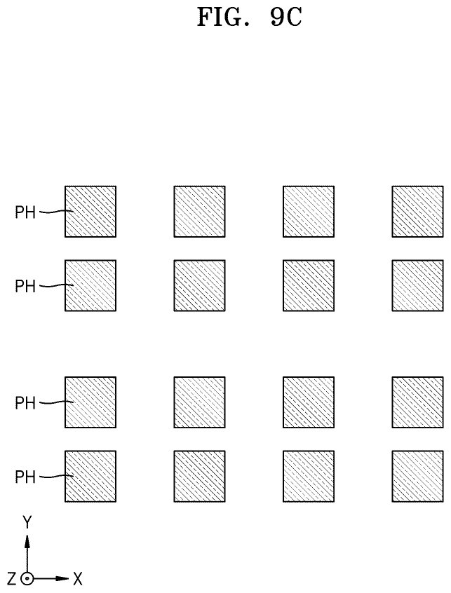

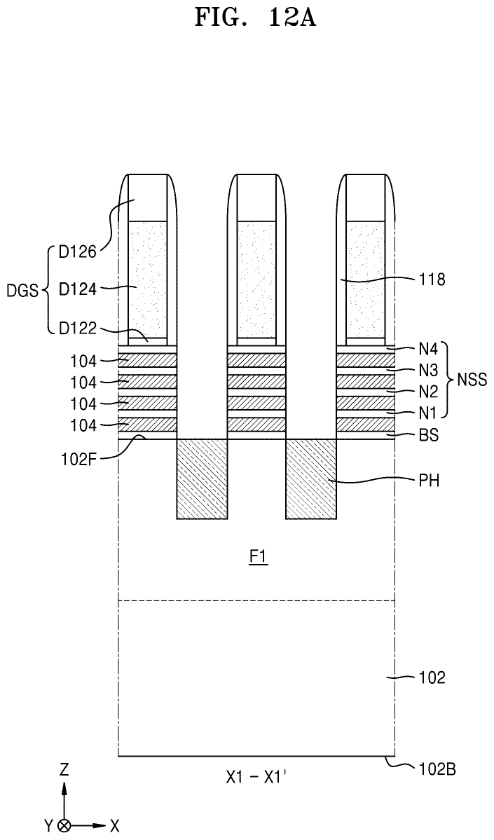

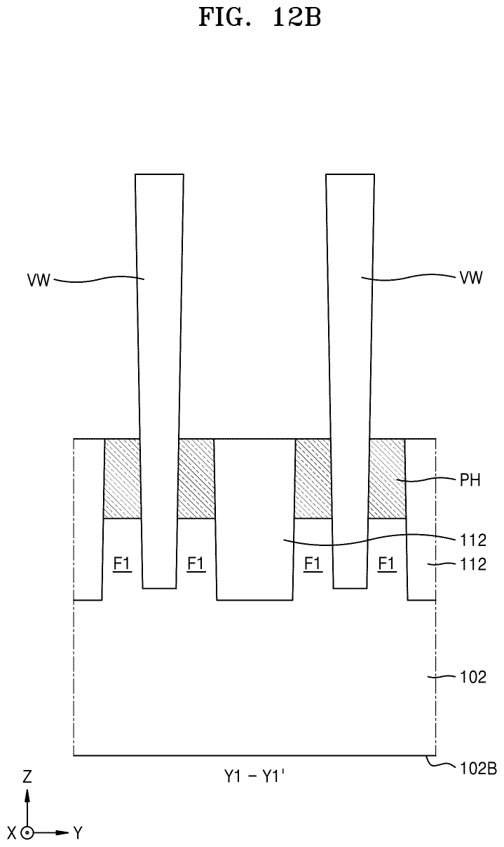

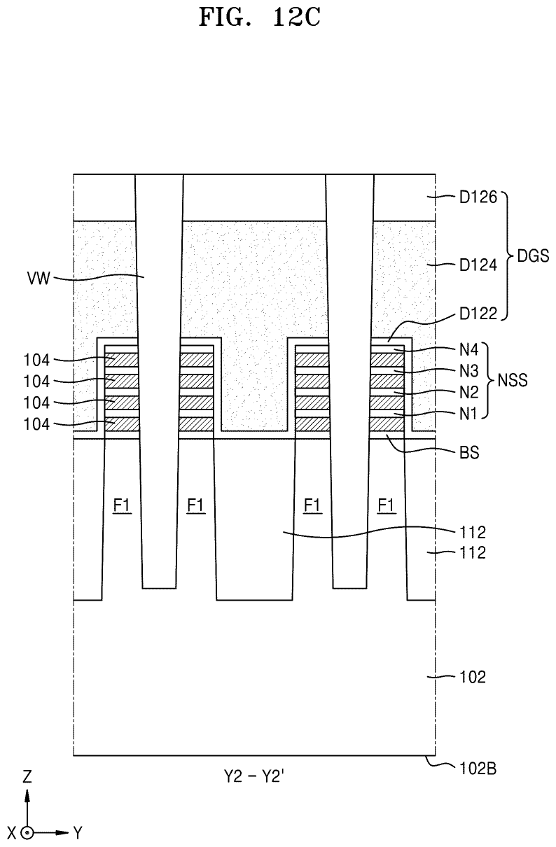

FIGS. 8A to 20B are diagrams of a process sequence of a method of manufacturing an IC device, according to embodiments. More specifically, FIGS. 8A, 9A, 10A, 11A, 12A, 13A, 14A, 15A, 16A, 17A, 18A, 19A, and 20A are cross-sectional views of an example sectional structure of a portion corresponding to the cross-section taken along line X1-X1′ of FIG. 1, according to a process sequence. FIGS. 8B, 9B, 10B, 11B, 12B, 13B, 16B, 17B, 18B, 19B, and 20B are cross-sectional views of an example sectional structure of a portion corresponding to the cross-section taken along line Y1-Y1′ of FIG. 1, according to a process sequence. FIGS. 12C, 14B, 15B, 16C, 17C, and 18C are cross-sectional views of an example sectional structure of a portion corresponding to the cross-section taken along line Y2-Y2′ of FIG. 1, according to a process sequence. FIGS. 8C and 9C are plan views of some components according to a process sequence. An example of a method of manufacturing the IC device 100 described with reference to FIGS. 1 to 4 is described with reference to FIGS. 8A to 20B. In FIGS. 8A to 20B, the same reference numerals are used to denote the same elements as in FIGS. 1 to 4, and detailed descriptions thereof are omitted.

Referring to FIGS. 8A, 8B, and 8C, a substrate 102 having a frontside surface 102F and a backside surface 102B, which are opposite to each other, may be provided, and a partial region may be etched from the frontside surface 102F of the substrate 102 may be etched by using a photolithography process, and thus, a plurality of place holder spaces PHS may be formed in the substrate 102. The plurality of place holder spaces PHS may be at the same positions as positions of a plurality of backside contact structures (refer to DBCS in FIG. 1) to be finally formed.

As illustrated in FIG. 8C, a planar shape of each of the plurality of place holder spaces PHS may have a rectangular shape with each side extending in a straight line. In the planar shape of each of the plurality of place holder spaces PHS, a size of a side HX in a first lateral direction (X direction) may be substantially equal to a size of each of the plurality of backside contact structures (refer to DBCS in FIG. 1) to be finally formed, in the first lateral direction (X direction). In the planar shape of each of the plurality of place holder spaces PHS, a size of a side HY in a second lateral direction (Y direction) may be greater than a size of each of the plurality of backside contact structures (refer to DBCS in FIG. 1) to be finally formed, in the second lateral direction (Y direction).

Referring to FIGS. 9A, 9B, and 9C, in the resultant structure of FIGS. 8A, 8B, and 8C, a plurality of place holders PH may be formed to fill the plurality of place holder spaces PHS. Each of the plurality of place holders PH may be formed to have a planarized top surface at the same vertical level of the frontside surface 102F of the substrate 102.

In embodiments, each of the plurality of place holders PH may include a doped SiGe film, an undoped SiGe film, a polysilicon film, a silicon nitride layer, a silicon carbonitride film (SiCN film), a silicon oxycarbonitride film (SiOCN film), a silicon oxide layer, or a combination thereof, without being limited thereto.

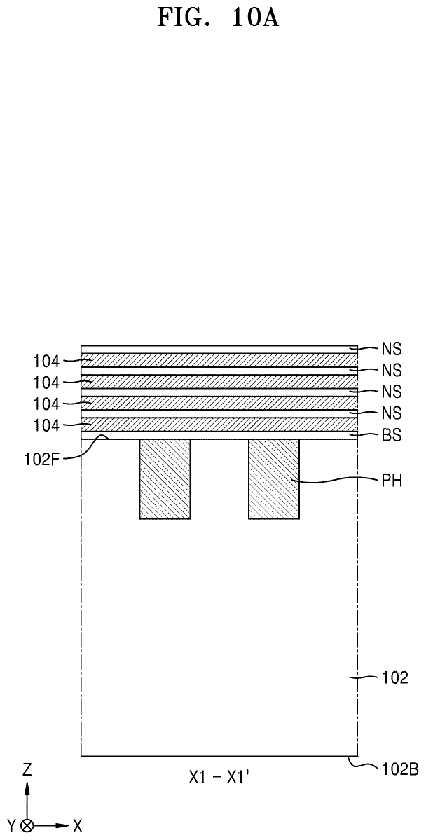

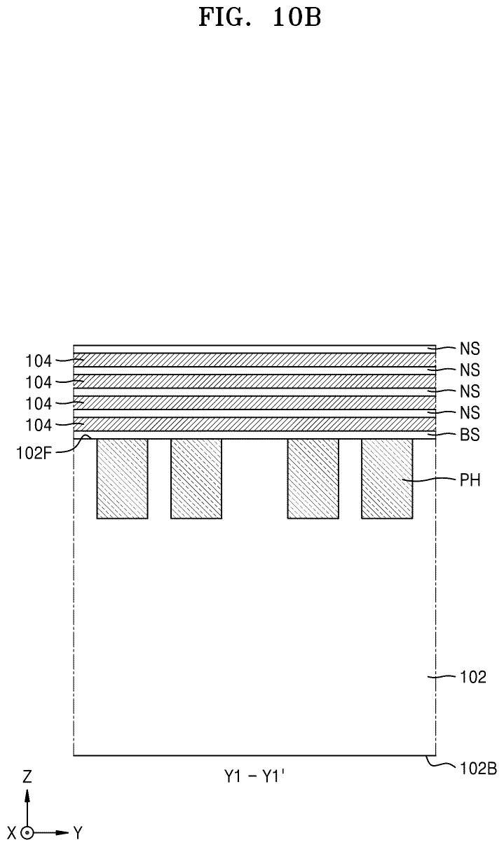

Referring to FIGS. 10A and 10B, in the resultant structure of FIGS. 9A, 9B, and 9C, a bottom semiconductor layer BS may be formed on the plurality of place holders PH and the frontside surface 102F of the substrate 102, and a stack structure in which a plurality of sacrificial semiconductor layers 104 and a plurality of nanosheet semiconductor layers NS may be alternately stacked one-by-one on the bottom semiconductor layer BS.

In the stack structure, the plurality of sacrificial semiconductor layers 104 and the plurality of nanosheet semiconductor layers NS may include semiconductor materials having different etch selectivities from each other. In embodiments, each of the plurality of nanosheet semiconductor layers NS may include a silicon (Si) layer, and each of the plurality of sacrificial semiconductor layers 104 may include a silicon germanium (SiGe) film. The SiGe film included in the sacrificial semiconductor layer 104 may have a Ge content ratio selected in a range of about 5 atomic percent (at %) to about 50 at % (e.g., about 10 at % to about 40 at %).

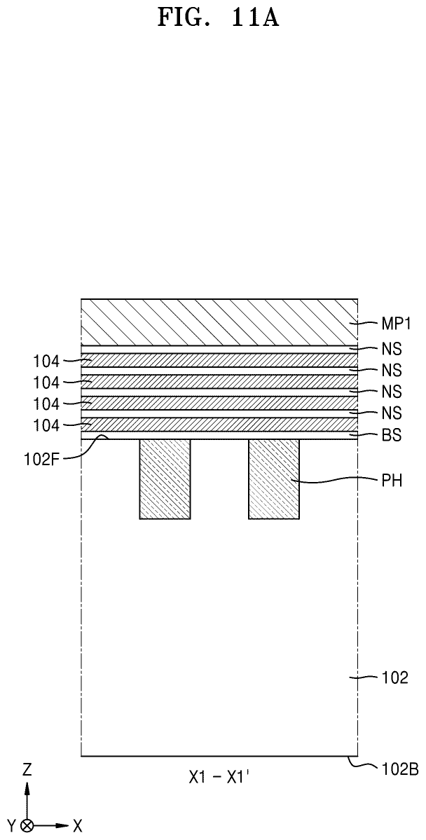

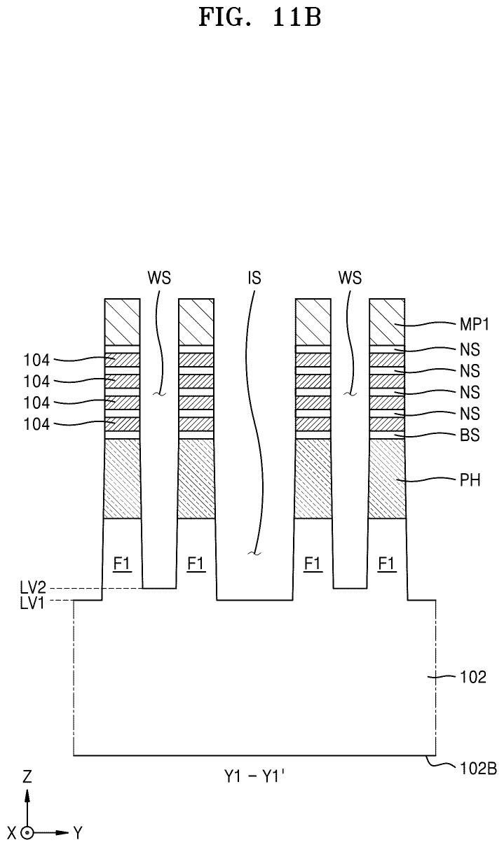

Referring to FIGS. 11A and 11B, a mask pattern MP1 having openings exposing a top surface of the stack structure may be formed on the resultant structure of FIGS. 10A and 10B. The mask pattern MP1 may include a stack structure of a silicon oxide layer pattern and a silicon nitride layer pattern. The mask pattern MP1 may include portions extending parallel to each other in the first lateral direction (X direction) on the substrate 102.

A portion of each of the plurality of sacrificial semiconductor layers 104, the plurality of nanosheet semiconductor layers NS, the bottom semiconductor layer BS, the plurality of place holders PH, and the substrate 102 may be etched by using the mask pattern MP1 as an etch mask. Thus, a plurality of wall spaces WS for forming the insulating wall (refer to VW in FIGS. 1 to 4) and a plurality of device isolation spaces IS for forming the device isolation film (refer to 112 in FIGS. 2B and 2C) may be formed on the substrate 102. By partially removing the substrate 102, a plurality of semiconductor regions F1 protruding upward from the substrate 102 in a vertical direction (Z direction) may be formed, and respective portions of the plurality of wall spaces WS and the plurality of device isolation spaces IS may be defined by the plurality of semiconductor regions F1.

As shown in FIG. 11B, a depth of each of the plurality of device isolation spaces IS may be greater than a depth of each of the plurality of wall spaces WS. As a result, a vertical level LV1 of the substrate 102 exposed at the bottom of each of the plurality of device isolation spaces IS may be closer to the backside surface 102B of the substrate 102 than a vertical level LV2 of the substrate 102 exposed at the bottom of each of the plurality of wall spaces WS.

Referring to FIGS. 12A, 12B, and 12C, after the mask pattern MP1 is removed from the resultant structure of FIGS. 11A and 11B, a plurality of device isolation films 112 may be formed on the substrate 102 to fill the plurality of device isolation spaces IS. The device isolation film 112 may be formed to cover a sidewall of each of the semiconductor region F1 and the place holder PH in the device isolation space IS. The formation of the device isolation film 112 may include forming an insulating film having a thickness sufficient to fill the plurality of device isolation spaces IS on the resultant structure of FIGS. 11A and 11B and performing a recess process of removing a portion of the insulating film to form the device isolation film 112, which includes the remaining portion of the insulating film. After the device isolation film 112 is formed, a stack structure including the plurality of sacrificial semiconductor layers 104 and the plurality of nanosheet semiconductor layers NS that remain on the substrate 102 may protrude over a top surface of the device isolation film 112, and a top surface of an uppermost one of the plurality of nanosheet semiconductor layers NS may be exposed.

Thereafter, a plurality of dummy gate structures DGS covering the plurality of sacrificial semiconductor layers 104 and the plurality of nanosheet semiconductor layers NS and a plurality of insulating spacers 118 covering both sidewalls of each of the plurality of dummy gate structures DGS may be formed. Each of the plurality of dummy gate structures DGS may be formed to extend long in the second lateral direction (Y direction). Each of the plurality of dummy gate structures DGS may include a dummy oxide film D122, a dummy gate layer D124, and a capping layer D126, which are sequentially stacked on a stack structure including the plurality of sacrificial semiconductor layers 104, and the plurality of nanosheet semiconductor layers NS. In embodiments, the dummy gate layer D124 may include polysilicon, and the capping layer D126 may include a silicon nitride layer.

Afterwards, a portion of each of the plurality of sacrificial semiconductor layers 104 and the plurality of nanosheet semiconductor layers NS and a portion of the bottom semiconductor layer BS may be etched by using the plurality of dummy gate structures DGS and the plurality of insulating spacers 118 as etch masks. As a result, the plurality of nanosheet semiconductor layers NS may be divided into a plurality of nanosheet stacks NSS including first to fourth nanosheets N1, N2, N3, and N4.

Thereafter, a plurality of insulating walls VW may be formed to fill the plurality of wall spaces WS. The plurality of insulating walls VW may be formed by using various methods. In embodiments, the formation of the plurality of insulating walls VW may include forming a planarized sacrificial film covering the resultant structure including the plurality of dummy gate structures DGS, the plurality of insulating spacers 118, and the plurality of nanosheet stacks NSS. The sacrificial film may include a material having an etch selectivity with respect to a material included in an outer surface of the dummy gate structure DGS. For example, the sacrificial film may include a silicon oxide layer. Afterwards, a portion of each of the sacrificial film, the plurality of dummy gate structures DGS, and the plurality of device isolation films 112 may be etched to form a plurality of openings corresponding to spaces in which the plurality of insulating walls VW are to be formed, the plurality of insulating walls VW may be formed to fill the plurality of openings, and the sacrificial film may be then removed. After the sacrificial film is removed, the plurality of place holders PH may be exposed on both sides of each of the plurality of insulating walls VW in the second lateral direction (Y direction). Although a process of forming the plurality of insulating walls VW by using the sacrificial film is described as an example, inventive concepts are not limited thereto, and various modifications and changes may be made in the scope of inventive concepts.

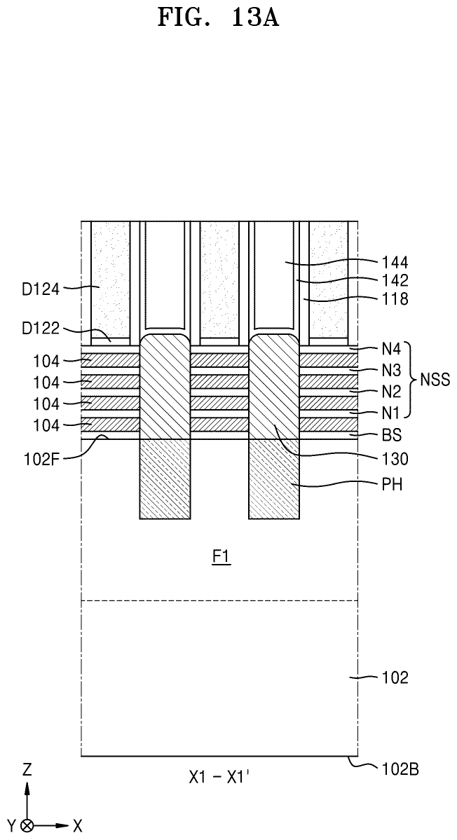

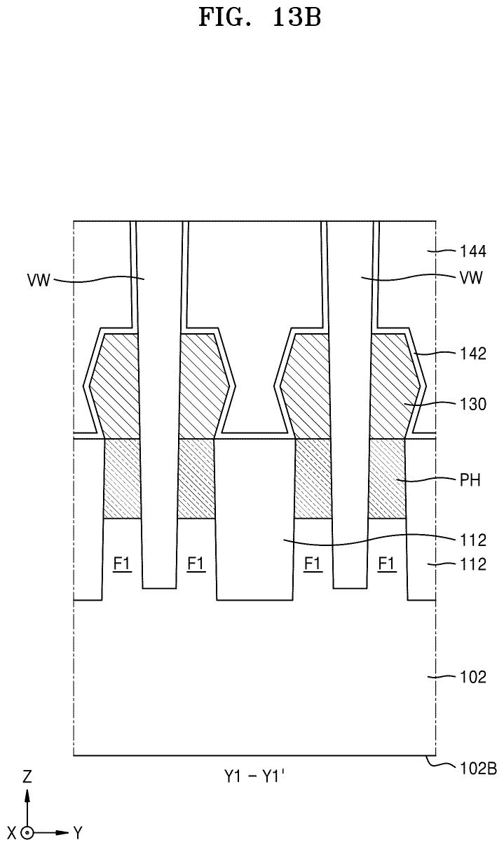

Referring to FIGS. 13A and 13B, a plurality of source/drain regions 130 may be formed on exposed top surfaces of the plurality of place holders PH in the resultant structure of FIGS. 12A to 12C. To form the plurality of source/drain regions 130, a semiconductor material may be epitaxially grown from a sidewall of each of the bottom semiconductor layer BS and the first to fourth nanosheets N1, N2, N3, and N4 that are exposed on the plurality of place holders PH. When the plurality of place holders PH include a SiGe film, a semiconductor material may be epitaxially grown from surfaces of the plurality of place holders PH during the formation of the plurality of source/drain regions 130.

Afterwards, an insulating liner 142 may be formed to cover surfaces of the resultant structure including the plurality of source/drain regions 130, and an inter-gate dielectric film 144 may be formed on the insulating liner 142. Next, a portion of each of the insulating liner 142 and the inter-gate dielectric film 144 may be etched to expose a top surface of each of a plurality of capping layers (refer to D126 in FIGS. 12A, 12B, and 12C) and the plurality of insulating walls VW. Thereafter, a portion of each of the plurality of insulating walls VW and the plurality of capping layers D126 may be removed to expose the dummy gate layer D124. The insulating liner 142 and the inter-gate dielectric film 144 may be partially removed such that a top surface of the inter-gate dielectric film 144, the top surfaces of the plurality of insulating walls VW, and the top surface of the dummy gate layer D124 become at substantially the same level.

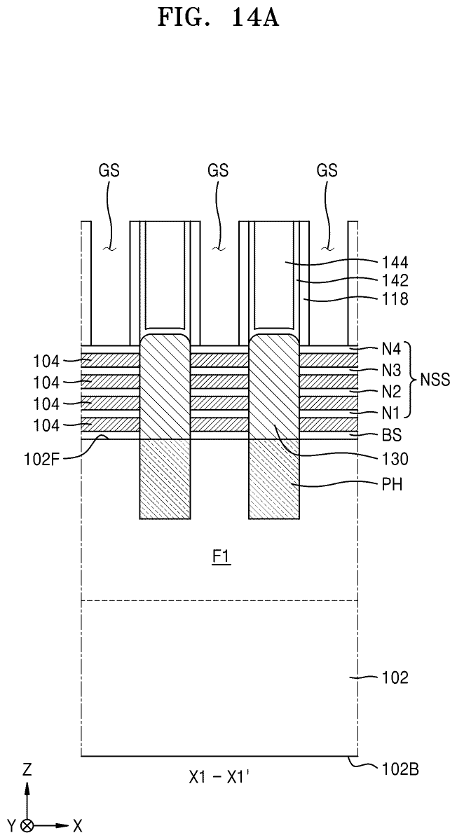

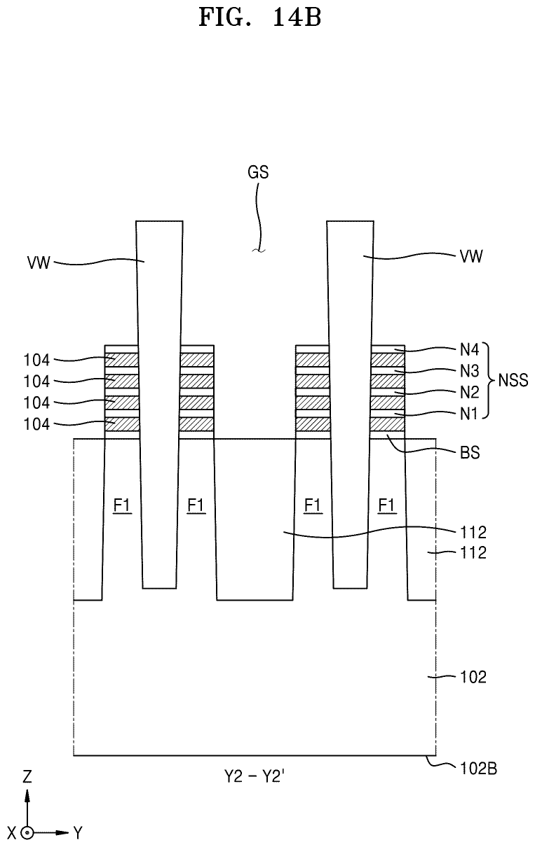

Referring to FIGS. 14A and 14B, the dummy gate layer D124 and the dummy oxide film D122 may be removed from the resultant structure of FIGS. 13A and 13B to prepare a gate space GS.

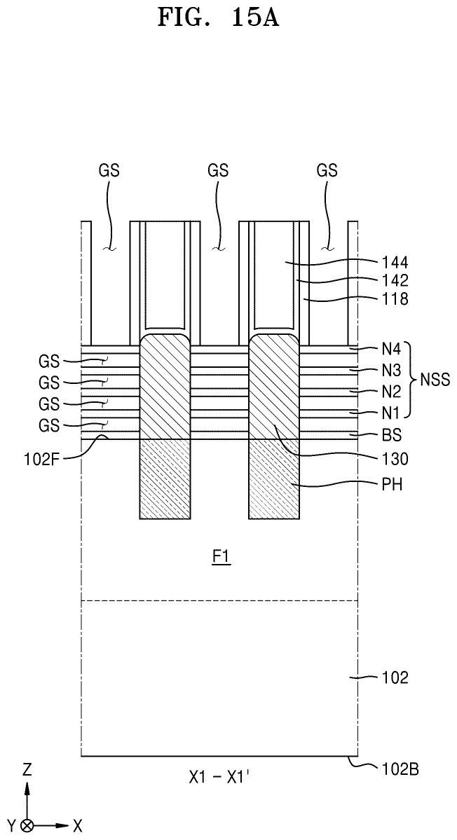

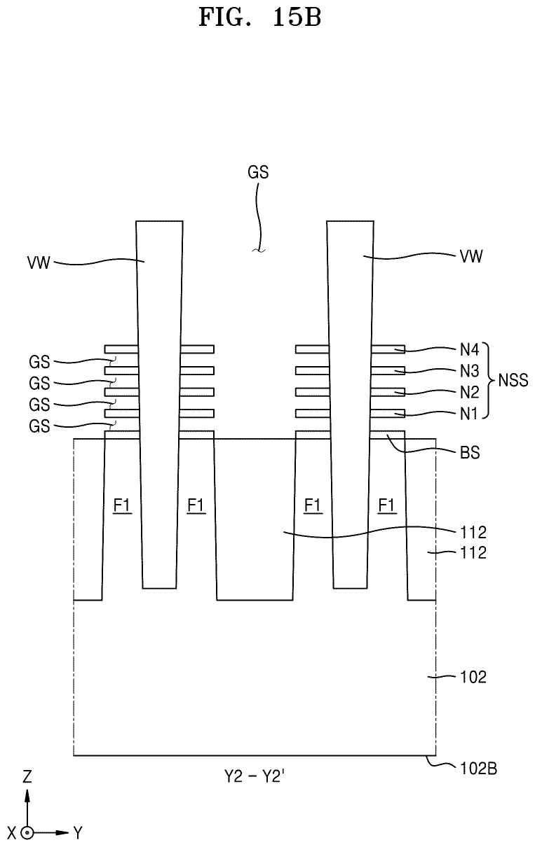

Referring to FIGS. 15A and 15B, the plurality of sacrificial semiconductor layers 104 remaining on the substrate 102 may be removed through the gate space GS from the resultant structure of FIGS. 14A and 14B. Thus, the gate space GS may extend to respective spaces between the first to fourth nanosheets N1, N2, N3, and N4 and a space between the bottom semiconductor layer BS and the first nanosheet N1.

In embodiments, to selectively remove the plurality of sacrificial semiconductor layers 104, differences in etch selectivity between each of the first to fourth nanosheets N1, N2, N3, and N4 and the bottom semiconductor layer BS and the plurality of sacrificial semiconductor layers 104 may be used. A liquid or gaseous etchant may be used to selectively remove the plurality of sacrificial semiconductor layers 104. In embodiments, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

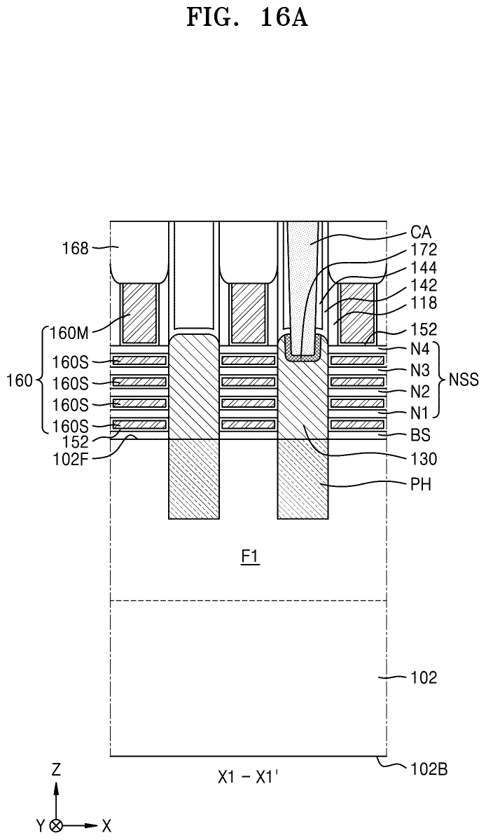

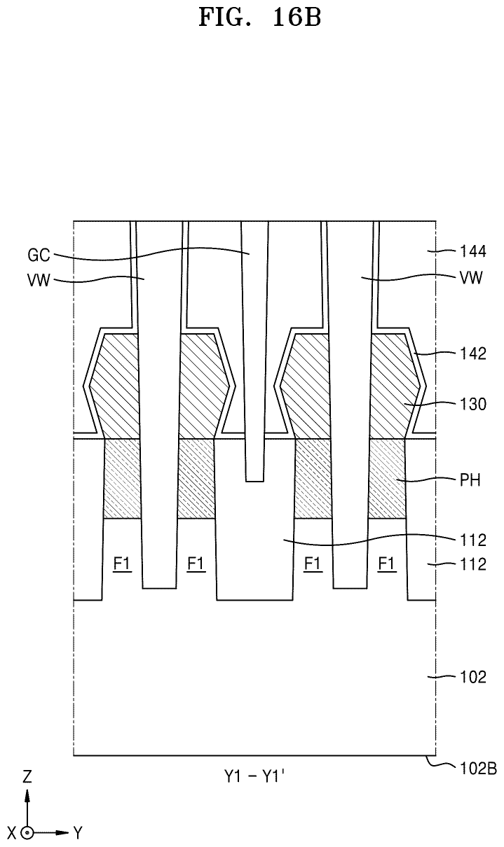

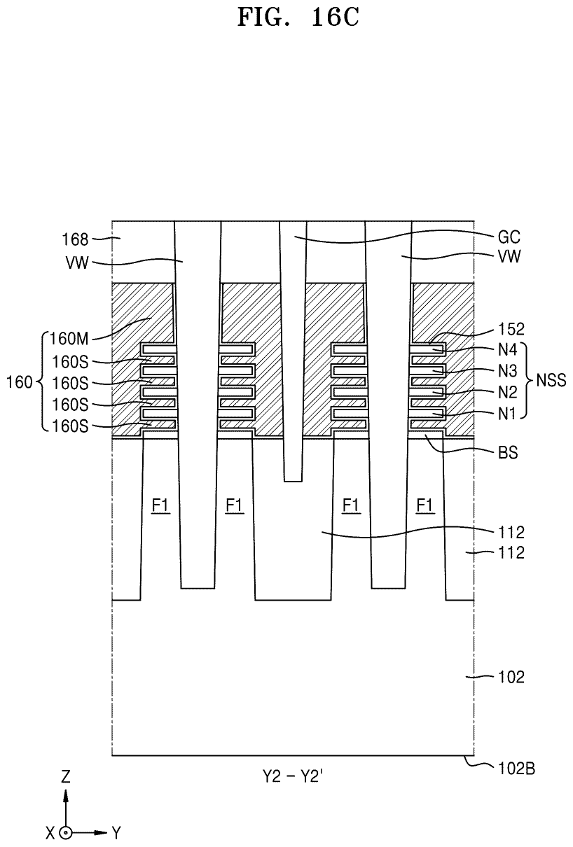

Referring to FIGS. 16A, 16B, and 16C, in the resultant structure of FIGS. 15A and 15B, a gate dielectric film 152 may be formed to cover respective exposed surfaces of the first to fourth nanosheets N1, N2, N3, and N4 and the bottom semiconductor layer BS. The gate dielectric film 152 may be formed by using an atomic layer deposition (ALD) process.

Thereafter, a gate line 160 filling the gate space (refer to GS in FIGS. 15A and 15B) may be formed on the gate dielectric film 152. Afterwards, a height of each of the gate line 160, the gate dielectric film 152, and the insulating spacer 118 may be reduced by removing a portion of each of the gate line 160, the gate dielectric film 152, and the insulating spacer 118 from a top surface of each thereof, and a plurality of capping insulating patterns 168 may be formed to cover the top surface of each of the gate line 160, the gate dielectric film 152, and the insulating spacer 118.

Subsequently, a source/drain contact hole exposing the source/drain region 130 may be formed between two adjacent ones of a plurality of gate lines 160, a metal silicide film 172 may be formed on a surface of the source/drain region 130 through the source/drain contact hole, and a frontside source/drain contact CA filling the source/drain contact hole may be formed on the metal silicide film 172.

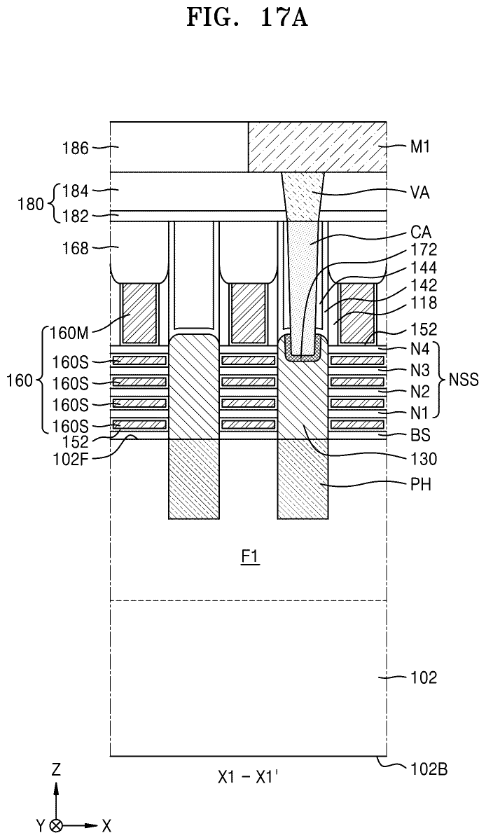

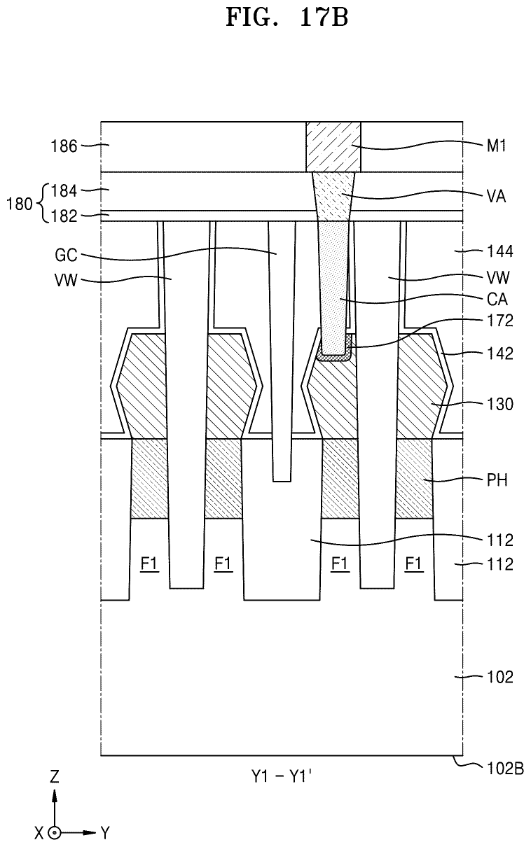

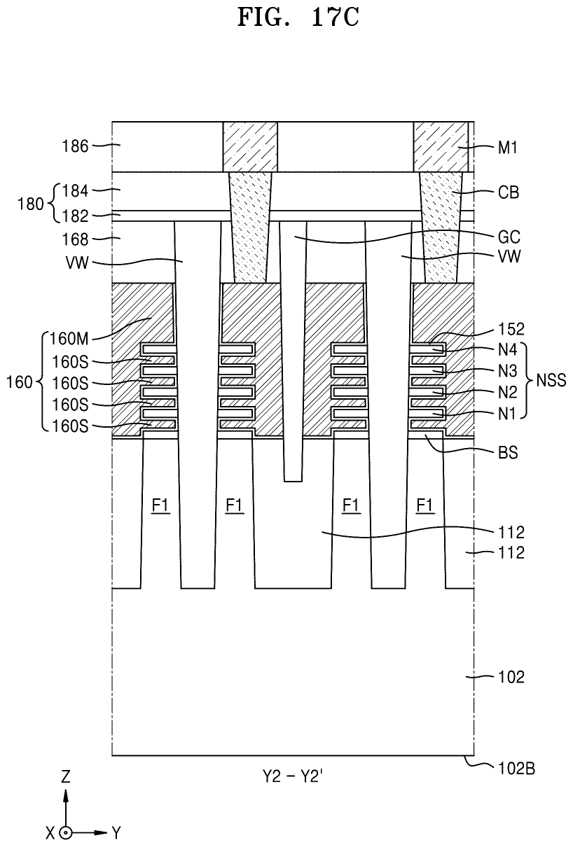

Referring to FIGS. 17A, 17B, and 17C, in the resultant structure of FIGS. 16A, 16B, and 16C, an etch stop film 182 and an upper insulating film 184 may be sequentially formed to cover the top surface of each of the frontside source/drain contact CA, the plurality of capping insulating patterns 168), the plurality of insulating walls VW, and the inter-gate dielectric film 144 to form an upper insulating structure 180. Thereafter, a source/drain via contact VA and a gate contact CB may be formed. The source/drain via contact VA may pass through the upper insulating structure 180 in the vertical direction (Z direction) and be connected to the frontside source/drain contact CA. The gate contact CB may pass through the upper insulating structure 180 and the capping insulating pattern 168 in the vertical direction (Z direction) and be connected to the gate line 160. The source/drain via contact VA and the gate contact CB may be formed simultaneously or by using separate processes. Afterwards, an interlayer insulating film 186 covering the upper insulating structure 180 and a plurality of upper wiring layers M1 passing through the interlayer insulating film 186 may be formed. The plurality of upper wiring layers M1 may include an upper wiring layer M1 connected to the source/drain via contact VA and an upper wiring layer M1 connected to the gate contact CB. Thereafter, a frontside wiring structure may be formed on the interlayer insulating film 186 and the plurality of upper wiring layers M1.

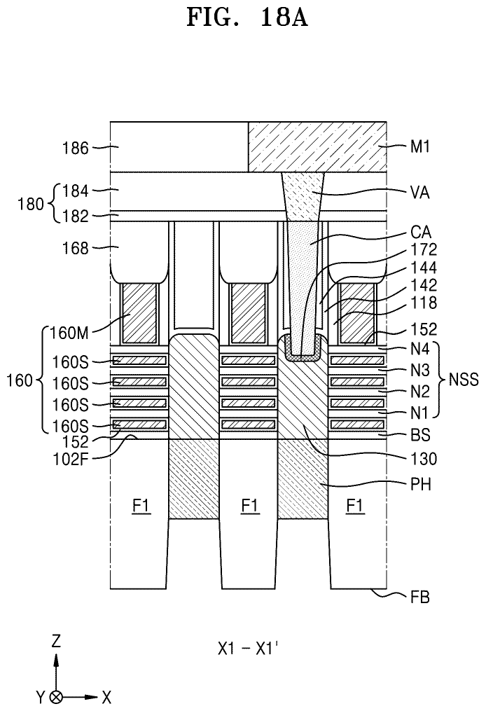

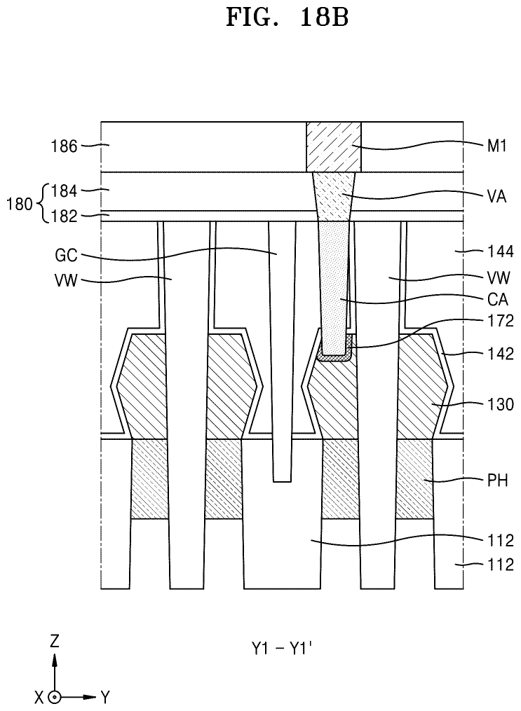

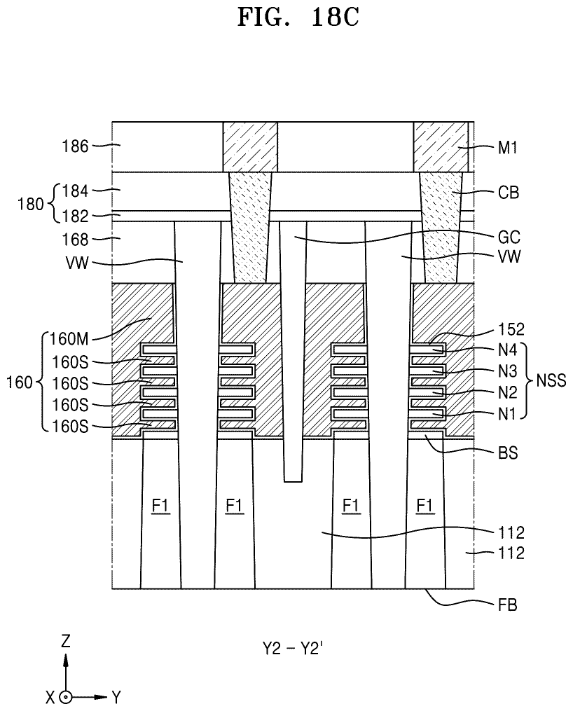

Referring to FIGS. 18A, 18B, and 18C, in the resultant structure of FIGS. 17A, 17B, and 17C, the backside surface 102B of the substrate 102 may be polished, and portions of the plurality of semiconductor regions F1 may be removed to expose the plurality of place holders PH.

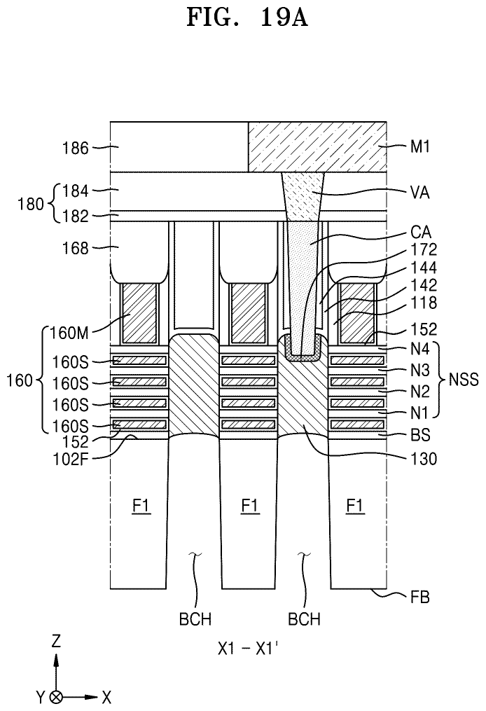

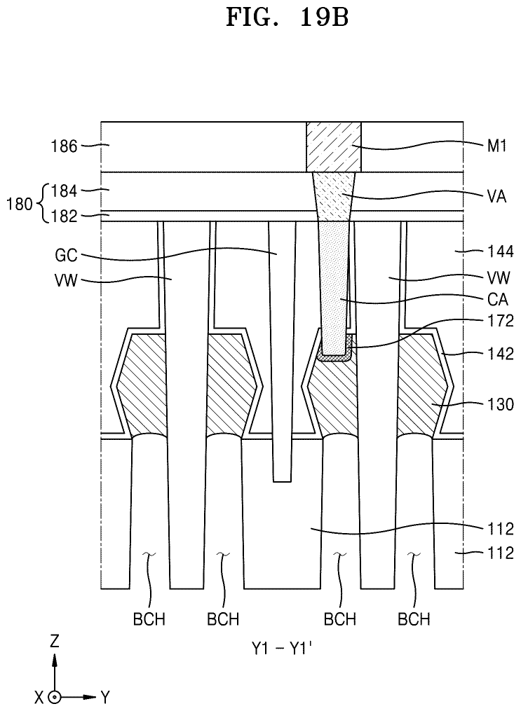

Referring to FIGS. 19A and 19B, the plurality of place holders PH may be removed from the resultant structure of FIGS. 18A, 18B, and 18C to form a plurality of backside contact holes BCH exposing the plurality of source/drain regions 130.

A width of each of the plurality of backside contact holes BCH in the first lateral direction (X direction) may be defined by two adjacent ones of the plurality of semiconductor regions F1, and a width of each of the plurality of backside contact holes BCH in the second lateral direction (Y direction) may be defined by the device isolation film 112 and the insulating wall VW. In the first lateral direction (X direction) and the second lateral direction (Y direction), a width of each of the plurality of backside contact holes BCH may gradually increase toward the backside surface FB of the semiconductor region F1.

During an etching process of removing the plurality of place holders PH, an exposed portion of the source/drain region 130 may be consumed, and thus, a surface shape of the source/drain region 130 toward the backside surface FB of the semiconductor region F1 may be deformed.

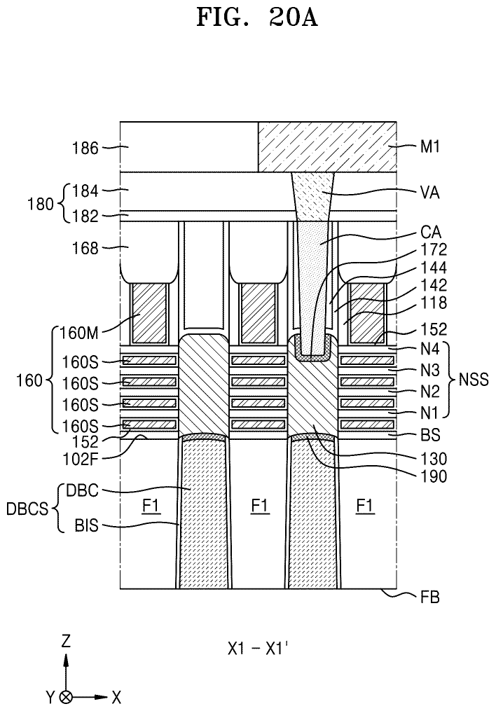

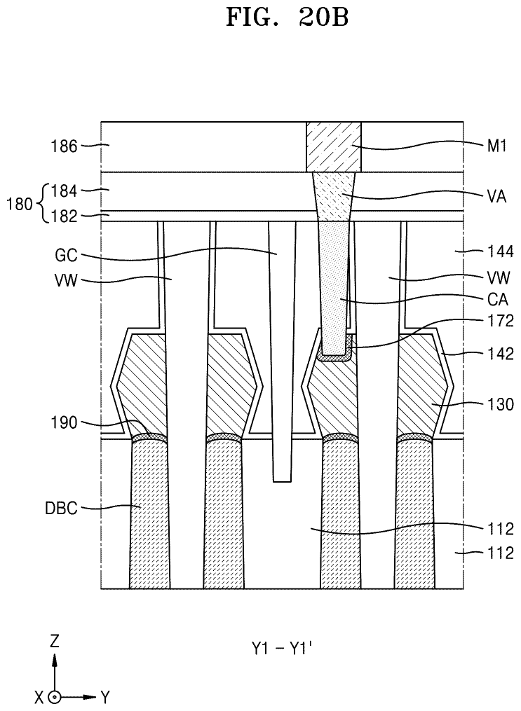

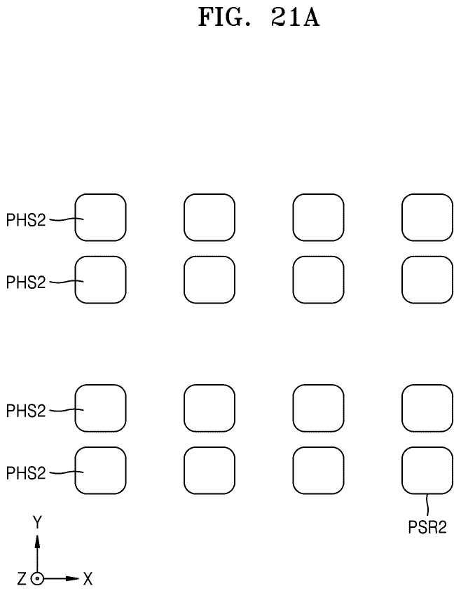

Referring to FIGS. 20A and 20B, in the resultant structure of FIGS. 19A and 19B, backside insulating spacers BIS may be formed to cover surfaces of the semiconductor regions F1, which are exposed at inner sidewalls of the plurality of backside contact holes BCH, and the plurality of backside contact holes BCH, each of which is defined by the backside insulating spacer BIS, the device isolation film 112, and the insulating wall VW, may be filled by a conductive material to form a plurality of backside contact structures DBCS.

According to the method of manufacturing the IC device 100 that has been described with reference to FIGS. 8A to 20B, before a stack structure including a plurality of sacrificial semiconductor layers 104 and a plurality of nanosheet semiconductor layers NS is formed on the substrate 102 to form a plurality of nanosheet stacks NSS, a plurality of place holder spacers PHS may be formed by etching a partial region from the frontside surface 102F of the substrate 102, and subsequently a plurality of place holders PH may be formed to fill the plurality of place holder spaces PHS. As described above, while steric hindrances, such as the plurality of insulating walls VW, the plurality of nanosheet stacks NSS, and the plurality of dummy gate structures DGS, are absent on the substrate 102, the plurality of place holder spaces PHS may be formed by etching the substrate 102, and the plurality of place holders PH filling the plurality of place holder spaces PHS may be formed. Thus, the difficulty of the etching process of forming the plurality of place holder spaces PHS may be reduced, a desired size of each of the plurality of place holders PH may be ensured, and a size deviation of the plurality of place holders PH may be minimized. Therefore, a backside contact DBC included in each of the plurality of backside contact structures DBCS to be finally formed by using the plurality of place holders PH may ensure a sufficient width in a lateral direction (X direction and/or Y direction). As a result, a contact resistance of each of a plurality of backside contacts DBC included in the plurality of backside contact structures DBCS may be reduced.

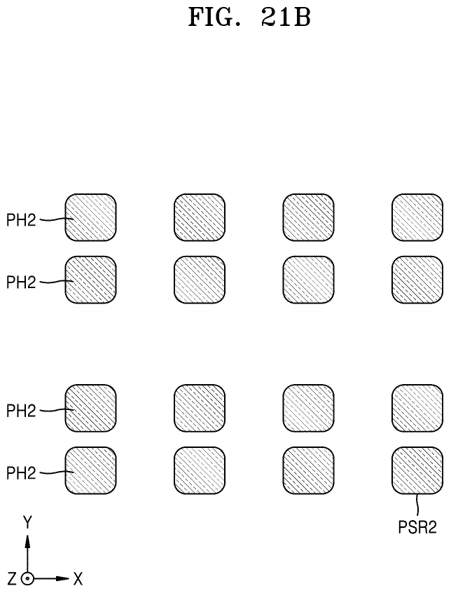

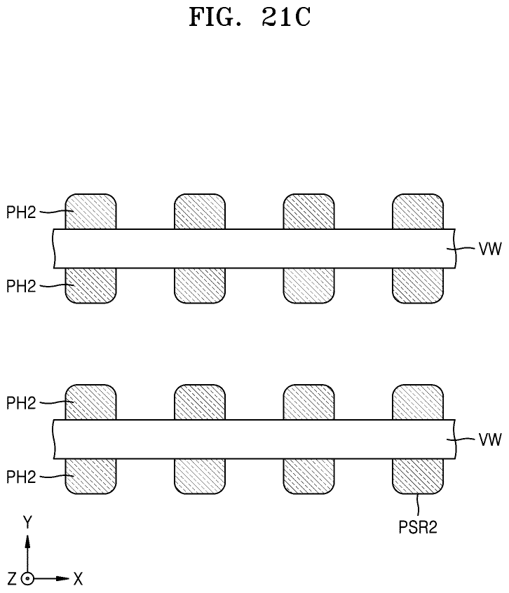

FIGS. 21A to 21C are plan views of a process sequence of a method of manufacturing an IC device, according to embodiments. An example of a method of manufacturing the IC device 200 described with reference to FIG. 5 is described with reference to FIGS. 21A to 21C. In FIG. 5, the same reference numerals are used to denote the same elements as in FIGS. 1 to 5 and detailed descriptions thereof are omitted.

Referring to FIG. 21A, by using a method similar to the process of forming the plurality of place holder spaces PHS, which has been described with reference to FIGS. 8A, 8B, and 8C, a partial region may be etched from the frontside surface 102F of the substrate 102, and thus, a plurality of place holder spaces PHS2 may be formed in the substrate 102. Each of the plurality of place holder spaces PHS2 may substantially have the same configuration as the place holder space PHS described with reference to FIGS. 8A, 8B, and 8C. However, each of the plurality of place holder spaces PHS2 may have a sidewall PSR2 of which a portion extends in a curved shape in a first lateral direction (X direction).

Referring to FIG. 21B, by using a method similar to the process of forming the plurality of place holders PH, which has been described with reference to FIGS. 9A, 9B, and 9C, a plurality of place holders PH2 may be formed to fill the plurality of place holder spaces PHS2 in the resultant structure of FIG. 21A.

Processes similar to those described with reference to FIGS. 10A to 17C may be performed on the resultant structure of FIG. 21B. As a result, as shown in FIG. 21C, structures including the plurality of place holders PH2 in contact with the insulating wall VW may be obtained on both sides of the insulating wall VW in the second lateral direction (Y direction).

In the resultant structure obtained according to the processes described with reference to FIGS. 17A, 17B, and 17C, the processes described with reference to FIGS. 18A to 20B may be performed on the structures including the plurality of place holders PH2 shown in FIG. 21C instead of the plurality of place holders PH, and thus, the IC device 200 described with reference to FIG. 5 may be manufactured.

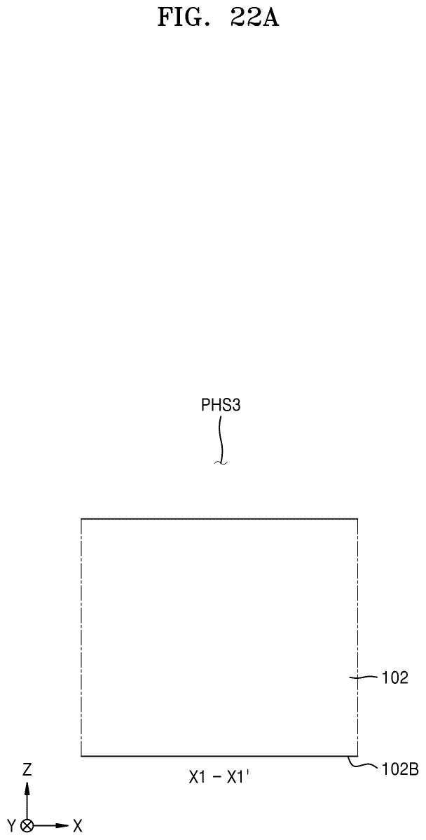

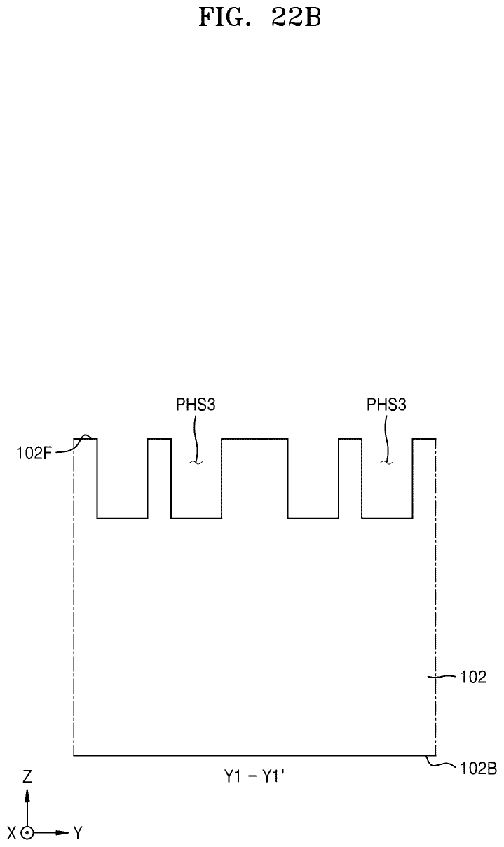

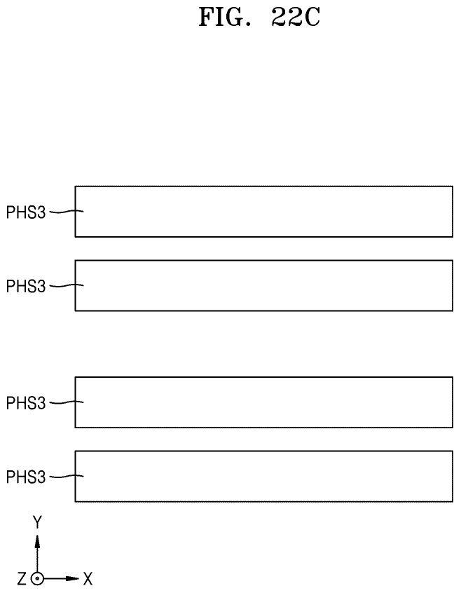

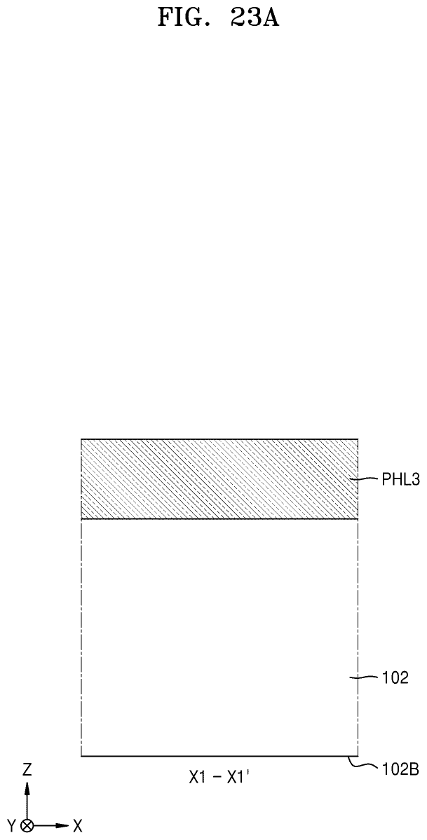

FIGS. 22A to 24C are diagrams of a process sequence of a method of manufacturing an IC device, according to embodiments. More specifically, FIGS. 22A, 23A, and 24A are cross-sectional views of an example sectional structure of a portion corresponding to the cross-section taken along line X1-X1′ of FIG. 1, according to a process sequence. FIGS. 22B, 23B, and 24B are cross-sectional views of an example sectional structure of a portion corresponding to the cross-section taken along line Y1-Y1′ of FIG. 1, according to a process sequence. FIGS. 22C, 23C, and 24C are plan views of some components according to a process sequence. An example of a method of manufacturing the IC device 300 described with reference to FIGS. 6A, 6B, and 6C is described with reference to FIGS. 22A to 24C. In FIGS. 22A to 24C, the same reference numerals are used to denote the same elements as in FIGS. 1 to 6C, and detailed descriptions thereof are omitted.

Referring to FIGS. 22A, 22B, and 22C, by using a method similar to the process of forming the plurality of place holder spaces PHS, which has been describe with reference to FIGS. 8A, 8B, and 8C, a partial region may be etched from the frontside surface 102F of the substrate 102, and thus, a plurality of place holder spaces PHS3 may be formed in the substrate 102.

Each of the plurality of place holder spaces PHS32 may substantially have the same configuration as the place holder space PHS described with reference to FIGS. 8A, 8B, and 8C. However, as shown in FIG. 22C, each of the plurality of place holder spaces PHS3 may have a bar shape extending linearly in a first lateral direction (X direction).

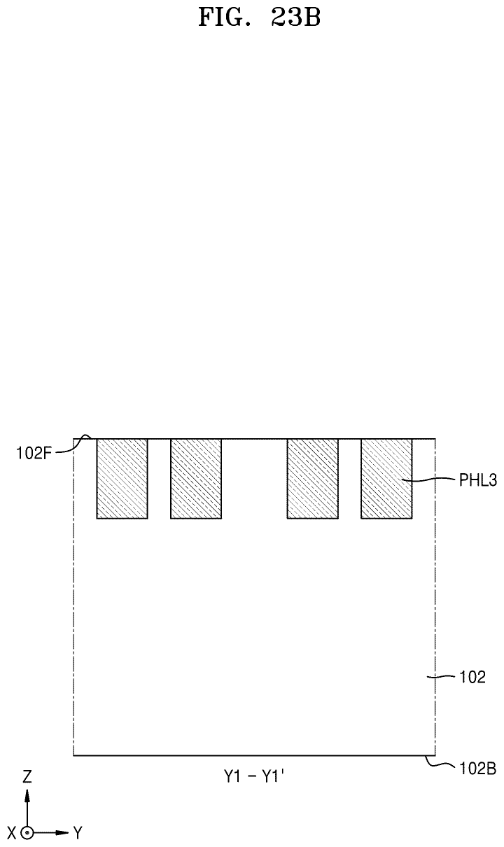

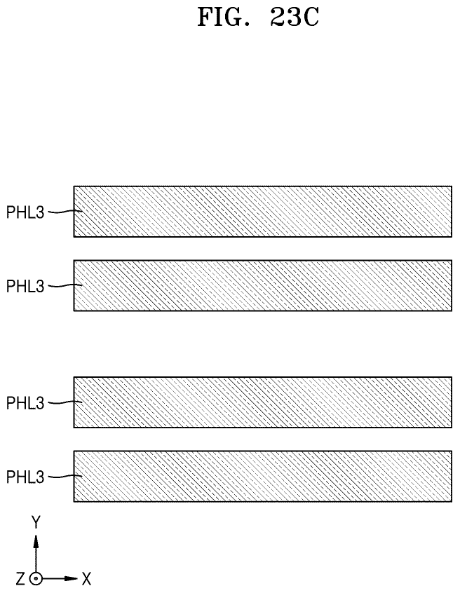

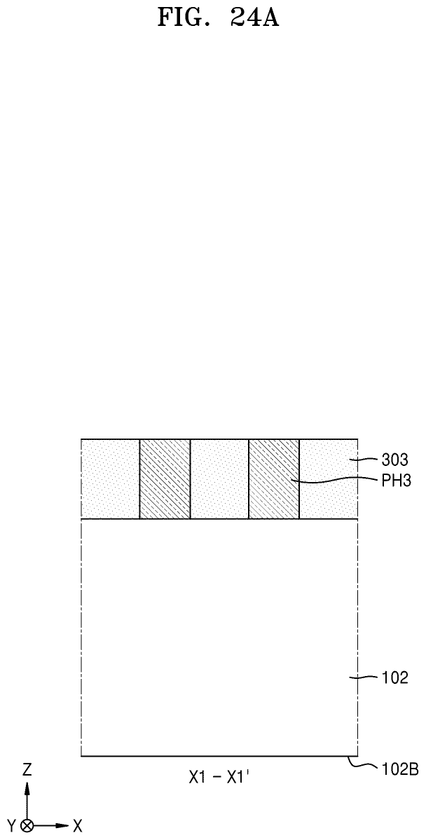

As shown in FIGS. 23A, 23B, and 23C, in the resultant structure of FIGS. 22A, 22B, and 22C, a plurality of place holder layers PHL3 may be formed to fill the plurality of place holder spaces PHS3. Each of the plurality of place holder layers PHL3 may be formed to have a planarized top surface at the same vertical level as the frontside surface 102F of the substrate 102.

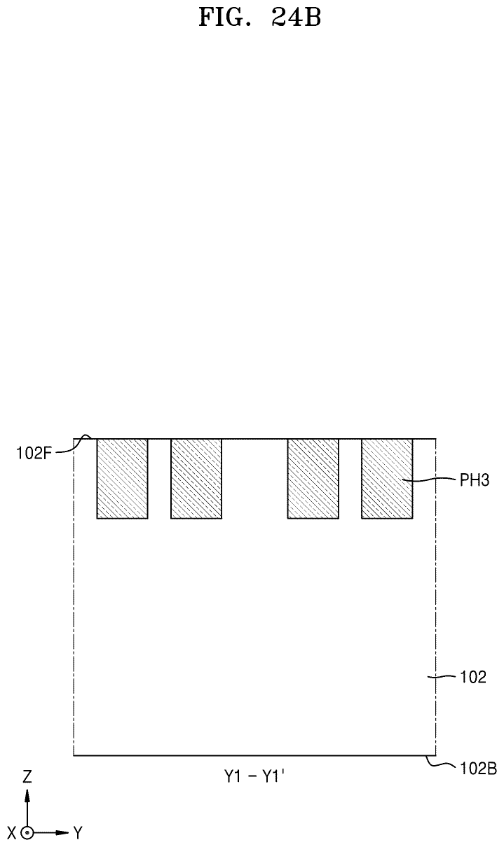

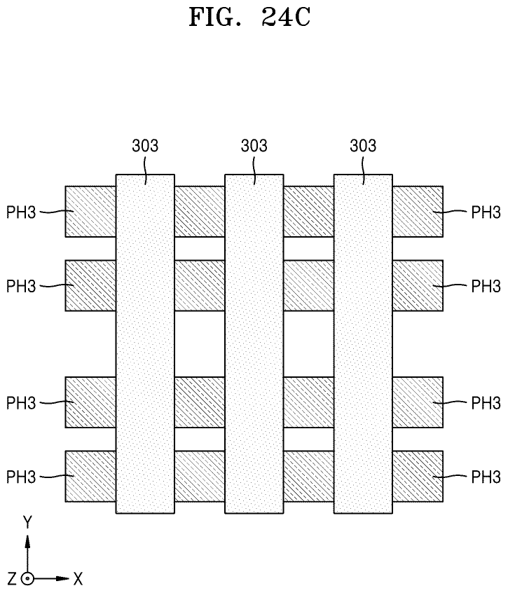

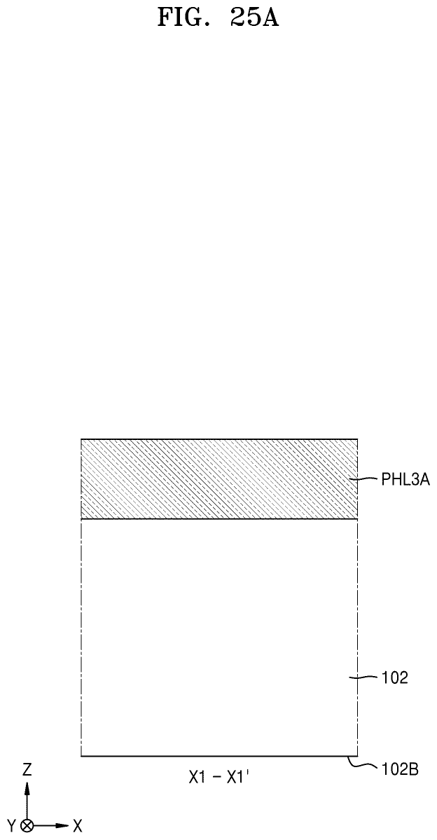

Referring to FIGS. 24A, 24B, and 24C, in the resultant structure of FIGS. 23A, 23B, and 23C, a portion of each of the substrate 102 and the plurality of place holder layers PHL3 may be etched to form a plurality of bar-shaped trenches extending long in a second lateral direction (Y direction), and a plurality of substituted semiconductor regions 303 may be formed by filling the plurality of trenches with a semiconductor material. As a result, one place holder layer PHL3 may be divided into a plurality of place holders PH3 by the plurality of substituted semiconductor regions 303. To form the plurality of substituted semiconductor regions 303, a semiconductor layer may be formed using an epitaxial growth process. The semiconductor layer may include silicon (Si).

Afterwards, processes similar to those described with reference to FIGS. 10A to 20B may be performed on the resultant structure of FIGS. 24A, 24B, and 24C, and the IC device 300 described with reference to FIGS. 6A, 6B, and 6C may be manufactured.

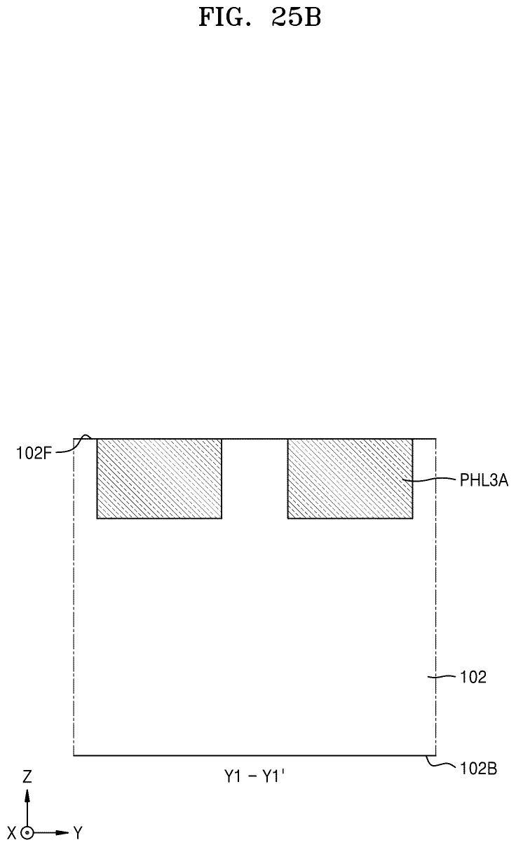

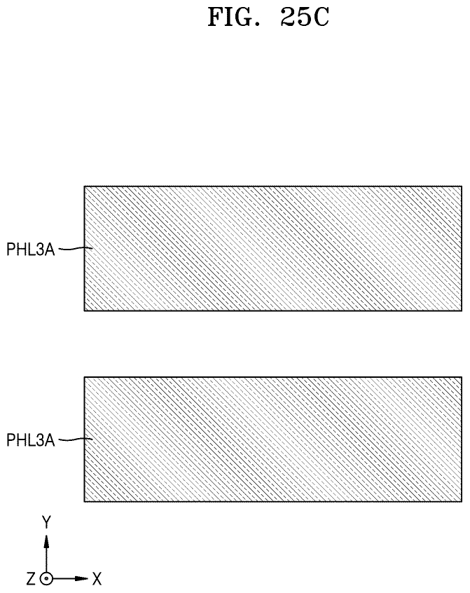

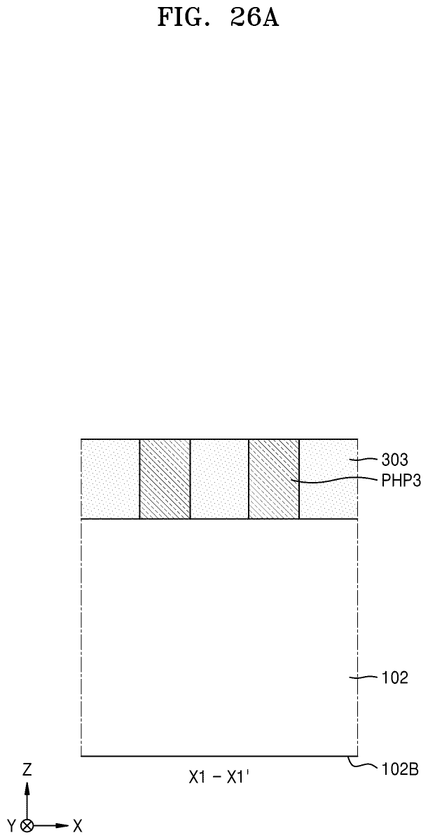

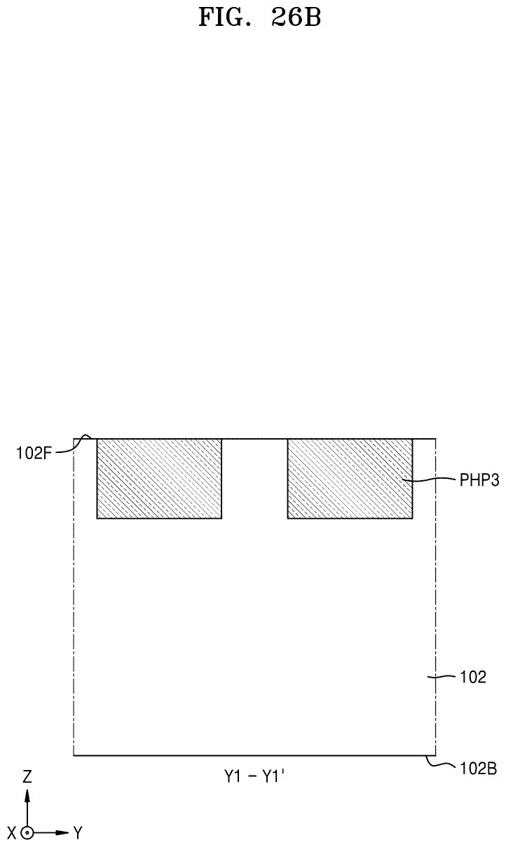

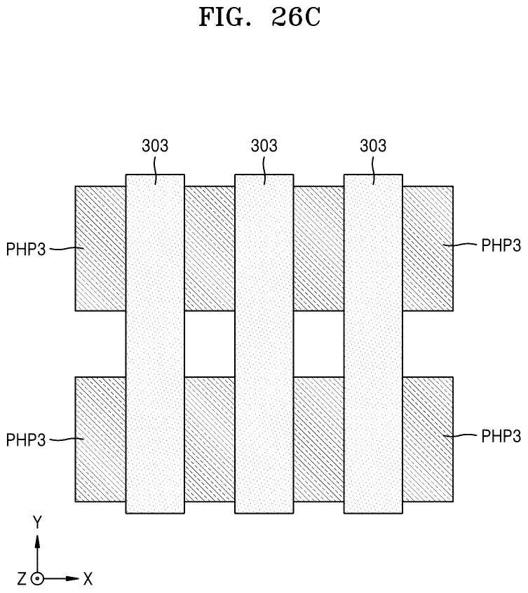

FIGS. 25A to 26C are diagrams of a process sequence of a method of manufacturing an IC device, according to embodiments. More specifically, FIGS. 25A and 26A are cross-sectional views of an example sectional structure of a portion corresponding to the cross-section taken along line X1-X1′ of FIG. 1, according to a process sequence. FIGS. 25B and 26B are cross-sectional views of an example sectional structure of a portion corresponding to the cross-section taken along line Y1-Y1′ of FIG. 1, according to a process sequence. FIGS. 25C and 26C are plan views of some components according to a process sequence. An example of a method of manufacturing the IC device 300 described with reference to FIGS. 6A, 6B, and 6C is described with reference to FIGS. 25A to 26C. In FIGS. 25A to 26C, the same reference numerals are used to denote the same elements as in FIGS. 1 to 6C, and detailed descriptions thereof are omitted.

Referring to FIGS. 25A, 25B, and 25C, processes similar to the process of forming the plurality of place holder layers PHL3, which has been described with reference to FIGS. 22A to 23C, may be performed, and thus, a plurality of place holder layers PHL3A may be formed in the substrate 102.

Each of the plurality of place holder layers PHL3A may substantially have the same configuration as the place holder layer PHL3 described with reference to FIGS. 23A, 23B, and 23C. However, a length of each of the plurality of place holder layers PHL3A in a second lateral direction (Y direction) may be greater than a length of each of the place holder layer PHL3 shown in FIGS. 23A, 23B, and 23C in the second lateral direction (Y direction). In embodiments, a length of each of the plurality of place holder layers PHL3A in the second lateral direction (Y direction) may correspond to a length in the second lateral direction (Y direction) of a region including a pair of place holder layers PHL3, which are adjacent to each other in the second lateral direction (Y direction), from among the plurality of place holder layers PHL3 shown in FIGS. 23A, 23B, and 23C, and a portion taken by a space between the pair of place holder layers PHL3.

Referring to FIGS. 26A, 26B, and 26C, in the resultant structure of FIGS. 25A, 25B, and 25C, a portion of each of the substrate 102 and the plurality of place holder layers PHL3A may be etched to form a plurality of bar-shaped trenches extending long in the second lateral direction (Y direction). Also, a plurality of substituted semiconductor regions 303 may be formed by filling the plurality of trenches with a semiconductor material by using a method similar to that described with reference to FIGS. 24A, 24B, and 24C. As a result, one place holder layer PHL3A may be divided into a plurality of preliminary place holders PHP3 by the plurality of substituted semiconductor regions 303.

Afterwards, processes similar to those described with reference to FIGS. 10A to 11B may be performed on the resultant structure of FIGS. 26A, 26B, and 26C. Herein, as described above with reference to FIGS. 11A and 11B, during an etching process of forming a plurality of wall spaces WS and a plurality of device isolation spaces IS, the plurality of wall spaces WS may be formed to respectively pass through the plurality of preliminary place holders PHP3 and the plurality of substituted semiconductor regions 303, which are shown in FIGS. 26A, 26B, and 26C, in the second lateral direction (Y direction). As a result, one preliminary place holder PHP3 may be divided into two, and thus, a plurality of place holders PH3 shown in FIGS. 24A, 24B, and 24C may be obtained. Processes similar to those described with reference to FIGS. 12A to 20B may be performed on the resultant structure, and thus, the IC device 300 described with reference to FIGS. 6A, 6B, and 6C may be manufactured.

Similar to the method of manufacturing the IC device 100 that has been described with reference to FIGS. 8A to 20B, according to the methods of manufacturing the IC devices 200 and 300 that have been described with reference to FIGS. 21A to 26C, before a stack structure including a plurality of sacrificial semiconductor layers 104 and a plurality of nanosheet semiconductor layers NS is formed to form a plurality of nanosheet stacks NSS, a structure required to form a plurality of place holders may be formed in the substrate 102. As described above, while steric hindrances, such as a plurality of insulating walls VW, the plurality of nanosheet stacks NSS, and a plurality of dummy gate structures DGS, are absent on the substrate 102, the structure required to form the plurality of place holders may be formed in the substrate 102. Thus, the difficulty of an etching process of forming a plurality of place holder spaces may be reduced, a desired size of each of the plurality of place holders may be ensured, and a size deviation of the plurality of place holders may be minimized. Therefore, a plurality of backside contacts to be finally formed by using the plurality of place holders may ensure a sufficient width in a lateral direction (X direction and/or Y direction). As a result, a contact resistance of each of the plurality of backside contacts may be reduced.

While inventive concepts has been particularly shown and described with reference to embodiments thereof, it will be understood that various changes in form and details may be made therein without departing from the spirit and scope of the following claims.

What is claimed is:

1. An integrated circuit device comprising:
a plurality of semiconductor regions, each of the plurality of semiconductor regions having a front surface and a backside surface that face opposite directions;
an insulating wall extending in a first lateral direction, the insulating wall passing in a vertical direction between a pair of semiconductor regions that are adjacent to each other in a second lateral direction, from among the plurality of semiconductor regions, the second lateral direction being perpendicular to the first lateral direction;
a pair of nanosheet stacks overlapping the pair of semiconductor regions in the vertical direction and facing frontside surfaces of the pair of semiconductor regions,
each nanosheet stack, among the pair of nanosheet stacks, including a nanosheet having one end contacting a sidewall of the insulating wall;
a pair of source/drain regions,
each source/drain region, among the pair of source/drain regions, including a portion in contact with the nanosheet of a corresponding one of the pair of nanosheet stacks; and
a backside contact having a contact end portion and a contact sidewall, wherein
the contact end portion is connected to a corresponding source/drain region among the pair of source/drain regions,
the contact sidewall contacts a sidewall of the insulating wall,
the backside contact extends in the vertical direction from the contact end portion toward the backside surface of each of the pair of semiconductor regions.

2. The integrated circuit device of claim 1, wherein
a width of the insulating wall in the second lateral direction gradually decreases as the insulating wall becomes closer toward the backside surface of each of the pair of semiconductor regions, and
a width of the backside contact in the second lateral direction gradually increases as the backside contact becomes closer toward the backside surface of each of the pair of semiconductor regions.

3. The integrated circuit device of claim 1, further comprising:
a metal silicide film between the corresponding source/drain region and the contact end portion of the backside contact, wherein
the metal silicide film contacts the insulating wall, and
the contact end portion of the backside contact is connected to the corresponding source/drain region through the metal silicide film.

4. The integrated circuit device of claim 1, further comprising:
a gate line surrounding the nanosheet in each of the pair of nanosheet stacks over the pair of semiconductor regions, the gate line extending in the second lateral direction; and
a gate cut insulating pattern facing an end of the gate line in the second lateral direction, the gate cut insulating pattern extending in the first lateral direction, wherein
a vertical level of a lowermost surface of the insulating wall is closer to the backside surface of each of the pair of semiconductor regions than a vertical level of a lowermost surface of the gate cut insulating pattern.

5. The integrated circuit device of claim 1, wherein
a wall lowermost surface of the insulating wall is coplanar with a contact lowermost surface of the backside contact, and
the wall lowermost surface of the insulating wall is closer to the backside surface of each of the pair of semiconductor regions than an upper surface of the insulating wall.

6. The integrated circuit device of claim 1, wherein
a distance between a contact lowermost surface of the backside contact and the backside surface of each of the pair of semiconductor regions is greater than a distance between a wall lowermost surface of the insulating wall and the backside surface of each of the pair of semiconductor regions.

7. The integrated circuit device of claim 1, wherein
in the backside contact, the contact sidewall and a sidewall opposite the contact sidewall extend in a straight line in the first lateral direction.

8. The integrated circuit device of claim 1, further comprising:
a backside insulating spacer between the backside contact and one of the semiconductor regions that is adjacent to the backside contact among the pair of semiconductor regions.

9. The integrated circuit device of claim 1, further comprising:
a pair of substituted semiconductor regions between the pair of semiconductor regions and the pair of nanosheet stacks, wherein
the pair of substituted semiconductor regions contact the pair of semiconductor regions,
each of the pair of semiconductor regions and the pair of substituted semiconductor regions comprise silicon (Si), and
the backside contact faces one of the pair of substituted semiconductor regions in the first lateral direction.

10. The integrated circuit device of claim 1, further comprising:
a device isolation film covering a first sidewall of each semiconductor region in the pair of semiconductor regions, wherein
each semiconductor region in the pair of semiconductor regions includes a second sidewall,
the second sidewall faces the insulating wall and is opposite the first sidewall in the second lateral direction, and
the device isolation film covers an other contact sidewall of the backside contact, and
the other contact sidewall of the backside contact is opposite the contact sidewall of the backside contact in contact with the insulating wall.

11. An integrated circuit device comprising:
a plurality of semiconductor regions spaced apart from each other in a first lateral direction and a second lateral direction that are perpendicular to each other, each of the plurality of semiconductor regions having a frontside surface and a backside surface that face opposite directions;
a plurality of nanosheet stacks facing the plurality of semiconductor regions in a vertical direction, each of the plurality of nanosheet stacks including a nanosheet;
a plurality of source/drain regions,
each of the plurality of source/drain regions being between a pair of nanosheet stacks that are adjacent to each other in the first lateral direction from among the plurality of nanosheet stacks, and
each of the plurality of source/drain regions contacting the nanosheet in an adjacent nanosheet stack adjacent among the plurality of nanosheet stacks;
an insulating wall,
the insulating wall passing in the vertical direction between a pair of semiconductor regions that are adjacent to each other in the second lateral direction among the plurality of semiconductor regions,
the insulating wall passing between a pair of nanosheet stacks that are adjacent to each other in the second lateral direction among the plurality of nanosheet stacks, and
the insulating wall passing between a pair of source/drain regions that are adjacent to each other in the second lateral direction from among the plurality of source/drain regions; and
a pair of backside contacts, wherein
each backside contact in the pair of backside contacts includes a contact end portion connected to a corresponding one of the pair of source/drain regions and a contact sidewall contacting the insulating wall, and
each backside contact in the pair of backside contacts extends from the contact end portion toward the backside surface of each of the pair of semiconductor regions in the vertical direction.

12. The integrated circuit device of claim 11, wherein
a width of the insulating wall in the second lateral direction gradually decreases as the insulating wall becomes closer toward the backside surface of each of the pair of semiconductor regions, and
a width of each of the pair of backside contacts in the second lateral direction gradually increases as the pair of backside contacts become closer toward the backside surface of each of the pair of semiconductor regions.

13. The integrated circuit device of claim 11, further comprising:
a plurality of gate lines extending in the second lateral direction on the frontside surface of each of the plurality of semiconductor regions; and
a gate cut insulating pattern facing one end of at least one of the plurality of gate lines in the second lateral direction, the gate cut insulating pattern extending in the first lateral direction, wherein
a vertical level of a lowermost surface of the insulating wall is closer to the backside surface of each of the pair of semiconductor regions than a vertical level of a lowermost surface of the gate cut insulating pattern.

14. The integrated circuit device of claim 11, wherein
in each of the pair of backside contacts, the contact sidewall and a sidewall opposite the contact sidewall extend in a straight line in the first lateral direction.

15. The integrated circuit device of claim 11, wherein each of the pair of backside contacts is apart from a most adjacent one of the plurality of semiconductor regions in the first lateral direction.

16. The integrated circuit device of claim 11, further comprising:
a plurality of substituted semiconductor regions between the plurality of semiconductor regions and the plurality of nanosheet stacks, the plurality of substituted semiconductor regions contacting the plurality of semiconductor regions, wherein
each of the plurality of semiconductor regions and the plurality of substituted semiconductor regions comprises silicon (Si), and
each of the pair of backside contacts is between an adjacent pair of substituted semiconductor regions among the plurality of substituted semiconductor regions in the first lateral direction.

17. The integrated circuit device of claim 11, further comprising:
a device isolation film covering a first sidewall of each semiconductor region in the pair of semiconductor regions, wherein
each semiconductor region in the pair of semiconductor regions includes a second sidewall,
the second sidewall faces the insulating wall and is opposite the first sidewall in the second lateral direction,
the device isolation film covers an other contact sidewall in each of the pair of backside contacts,
the other contact sidewall is opposite the contact sidewall in each of the pair of backside contacts, and
a device isolation lowermost surface of the device isolation film is coplanar with a wall lowermost surface of the insulating wall.

18. An integrated circuit device comprising:
a plurality of semiconductor regions spaced apart from each other in a first lateral direction and a second lateral direction that are perpendicular to each other, each of the plurality of semiconductor regions having a frontside surface and a backside surface that face opposite directions;
a plurality of nanosheet stacks facing the plurality of semiconductor regions in a vertical direction, each of the plurality of nanosheet stacks including a nanosheet;
a plurality of source/drain regions,
each of the plurality of source/drain regions being between a pair of nanosheet stacks that are adjacent to each other in the first lateral direction among the plurality of nanosheet stacks, and
each of the plurality of source/drain regions contacting the nanosheet in an adjacent nanosheet stack among the plurality of nanosheet stacks;
an insulating wall,
the insulating wall passing in the vertical direction between a pair of semiconductor regions that are adjacent to each other in the second lateral direction among the plurality of semiconductor regions,
the insulating wall passing between a pair of nanosheet stacks that are adjacent to each other in the second lateral direction among the plurality of nanosheet stacks, and
the insulating wall passing between a pair of source/drain regions that are adjacent to each other in the second lateral direction among the plurality of source/drain regions; and
a plurality of backside contact structures contacting the insulating wall, the plurality of backside contact structures being arranged in a line in the first lateral direction, wherein
each of the plurality of backside contact structures comprises a backside contact having a contact end portion connected to a corresponding one of the plurality of source/drain regions and a contact sidewall contacting the insulating wall,
the backside contact extends from the contact end portion toward the backside surface in the vertical direction,
a width of the backside contact in the second lateral direction gradually increases as the backside contact becomes closer toward the backside surface,
a width of the insulating wall in the second lateral direction gradually decreases as the insulating wall becomes closer toward the backside surface, and,
in each of the plurality of backside contact structures, the contact sidewall of the backside contact extends in a straight line in the first lateral direction.

19. The integrated circuit device of claim 18, further comprising:
a plurality of gate lines extending in the second lateral direction on the frontside surface of each of the plurality of semiconductor regions;
a device isolation film covering a first sidewall of each of the plurality of semiconductor regions, the first sidewall being opposite in the second lateral direction to a second sidewall of each of the plurality of semiconductor regions, the second sidewall facing the insulating wall; and
a gate cut insulating pattern facing one end of the plurality of gate lines in the second lateral direction and extending in the first lateral direction, the gate cut insulating pattern passing through a portion of the device isolation film in the vertical direction, wherein
a device isolation lowermost surface of the device isolation film is coplanar with a wall lowermost surface of the insulating wall, and
a lowermost surface of the gate cut insulating pattern, which is closest to the backside surface, is in contact with the device isolation film.

20. The integrated circuit device of claim 18, wherein,
in each of the plurality of backside contact structures, the contact sidewall and a sidewall opposite the contact sidewall extend in a straight line in the first lateral direction.
